(19) United States
(12) Patent Application Publication
(10) Pub. No.: US 2022/0158029 A1
(43) Pub. Date: May 19, 2022

(54) SUBSTRATE AND LIGHT EMITTING ELEMENT

(71) Applicant: TDK Corporation, Chuo-ku, Tokyo (JP)

(72) Inventors: Atsushi OHIDO, Chuo-ku, Tokyo (JP); Kazuhito YAMASAWA, Chuo-ku, Tokyo (JP)

(73) Assignee: TDK Corporation, Chuo-ku, Tokyo (JP)

(21) Appl. No.: 17/434,693

(22) PCT Filed: Feb. 27, 2020
(86) PCT No.: PCT/JP2020/008086

§ 371 Date: Aug. 27, 2021

(30) Foreign Application Priority Data
Mar. 6, 2019 (JP) 2019-040650
Mar. 6, 2019 (JP) 2019-040653

(51) Int. Cl. H01L 33/16; H01L 33/32

(52) U.S. Cl. CPC H01L 33/16; H01L 33/32

(57) ABSTRACT

A substrate 10 contains a first layer L1 and a second layer L2 that are stacked on one another, the first layer L1 contains crystalline AlN and an additive element, the second layer L2 contains crystalline α-alumina, the additive element is at least one selected from the group consisting of rare earth elements, alkaline earth elements, and alkali metal elements, the thickness of the first layer L1 is 5 to 600 nm, RC(002) is a rocking curve of diffracted X-rays originating from a (002) plane of AlN, RC(002) is measured by an ω-scan of the surface S_{L1} of the first layer L1, the half width of RC(002) is 0° to 0.4°, RC(100) is a rocking curve of diffracted X-rays originating from a (100) plane of AlN, RC(100) is measured by a ϕ-scan of the surface S_{L1} of the first layer L1, and the half width of RC(100) is 0° to 0.8°.

### TECHNICAL FIELD

The present invention relates to a substrate and a light emitting element.

### BACKGROUND ART

Nitrides of Group 13 elements, such as aluminum nitride (AlN), are semiconductors. Attention has been paid to crystals of nitrides of Group 13 elements as a material for light emitting elements that emit short wavelength light ranging from the blue band to the ultraviolet band.

For example, light emitting elements as described in the following Patent Literatures 1 and 2 contain a buffer layer formed from crystals of AlN. This buffer layer is formed on the surface of a sapphire substrate according to a metal organic chemical vapor deposition (MOCVD) method. As the buffer layer is interposed between a nitride semiconductor layer (GaN or the like) and a sapphire substrate, lattice mismatch between the nitride semiconductor and sapphire is suppressed, and threading dislocation attributable to lattice mismatch is suppressed. As a result, the crystallinity of the nitride semiconductor layer such as a light emitting layer is enhanced, and the luminous efficiency of the light emitting layer is also enhanced.

In a laminated substrate for a light emitting element as described in the following Patent Literature 3, a single crystal substrate of α-alumina, an aluminum oxynitride layer, and an aluminum nitride film are laminated in this order. This laminated substrate is produced by nitriding a single crystal substrate of α-alumina in the presence of carbon, nitrogen, and carbon monoxide. The following Patent Literature 3 discloses that the crystallinity of an aluminum nitride film is enhanced by forming an aluminum nitride film on an aluminum oxynitride layer.

### CITATION LIST

### Patent Literature

Patent Literature 1: International Publication WO 2013/005789
Patent Literature 2: Japanese Unexamined Patent Publication No. 2010-92934
Patent Literature 3: Japanese Unexamined Patent Publication No. 2005-104829

### SUMMARY OF INVENTION

### Technical Problem

### Object of First Present Invention

In a process in which a buffer layer (AlN) is formed on the surface of a sapphire substrate by a vapor deposition method, the sapphire substrate and the buffer layer are heated. The sapphire substrate and the buffer layer differ in coefficients of thermal expansion and different lattice constants. Therefore, stress is likely to act on the sapphire substrate and the buffer layer as a result of heating the sapphire substrate and the buffer layer. When the sapphire substrate and the buffer layer are warped by stress, the temperature of the sapphire substrate and the buffer layer is likely to become non-uniform. For example, a temperature difference is likely to occur between the central portion and the peripheral portion of the sapphire substrate. When the temperature of the sapphire substrate and the buffer layer is non-uniform, the buffer layer is unlikely to grow uniformly on the surface of the sapphire substrate. As a result, the composition of the buffer layer becomes non-uniform, and the crystallinity of the buffer layer is deteriorated. In other words, the elements constituting the buffer layer are likely to be non-uniformly distributed in the buffer layer, and crystal defects are likely to be formed in the buffer layer. As the composition of the buffer layer is non-uniform and the crystallinity of the buffer layer is deteriorated, the composition of each of the semiconductor layers formed on the surface of the buffer layer is also likely to become non-uniform, and the crystallinity of each of the semiconductor layers is also likely to be deteriorated. As a result, the standard deviation in the wavelength of the light emitted from the light emitting element increases, and the defect rate of the light emitting element increases.

It is an object of the first present invention to provide a substrate that reduces the standard deviation of the wavelength of the light emitted from a light emitting element, and a light emitting element containing the substrate.

### Object of Second Present Invention

The substrate and the light emitting element described in the above-described Patent Literatures 1 and 3 have the following technical problems.

In the process in which the buffer layer (AlN layer) is formed on the surface of the sapphire substrate by a vapor deposition method, the sapphire substrate and the AlN layer are heated. Sapphire and AlN differ in coefficients of thermal expansion and different lattice constants. Therefore, as a result of heating of the sapphire substrate and the AlN layer, stress is likely to act on the interface between the sapphire substrate and the AlN layer. As stress acts on the interface between the sapphire substrate and the AlN layer, the sapphire substrate and the AlN layer are easily cracked. Cracks are likely to be formed at the interface where stress is concentrated. Sapphire and aluminum oxynitride (AlON) also differ in coefficients of thermal expansion and different lattice constants, and AlON and AlN also differ in coefficients of thermal expansion and different lattice constants. Therefore, even in a case where an AlON layer is disposed between a sapphire substrate and an AlN layer, stress is likely to act on these interfaces, and the sapphire substrate, the aluminum oxynitride layer, and the AN layer are easily cracked.

When the sapphire substrate and the AlN layer are warped by the above-described stress, the temperature of the sapphire substrate and the AlN layer is likely to become non-uniform. For example, a temperature difference is likely to occur between the central portion and the peripheral portion of the sapphire substrate. When the temperature of the sapphire substrate and the AlN layer is non-uniform, the AlN layer is not likely to grow uniformly at the surface of the sapphire substrate. As a result, the composition of the AlN layer becomes non-uniform, and the crystallinity of the AN layer is deteriorated. In other words, Al and N are likely to be distributed non-uniformly in the buffer layer, and crystal defects are likely to be formed in the AlN layer. As the composition of the AlN layer is non-uniform and the crystallinity of the AlN layer is deteriorated, the surface of the AlN layer is roughened. As each of semiconductor layers is formed on a rough surface of the AlN layer, the composition of each of the semiconductor layers is also likely to become non-uniform, the crystallinity of each of the semiconductor layers is also likely to be deteriorated, and the surface of each of the semiconductor layers is also roughened. As a result, it is difficult to produce a light emitting element that normally operates.

It is an object of the second present invention to provide a substrate that is less likely to crack and has a smooth surface, and a light emitting element containing the substrate.

### Solution to Problem

### First Present Invention

A substrate according to an aspect of a first present invention contains a first layer and a second layer on which the first layer is stacked, the first layer contains crystalline aluminum nitride and an additive element, the second layer contains crystalline α-alumina, the additive element is at least one selected from the group consisting of rare earth elements, alkaline earth elements, and alkali metal elements, a thickness of the first layer is from 5 nm to 600 nm, RC(002) is a rocking curve of diffracted X-rays originating from a (002) plane of aluminum nitride, RC(002) is measured by an ω-scan of the surface of the first layer, a half width of RC(002) is from 0° to 0.4°, RC(100) is a rocking curve of diffracted X-rays originating from a (100) plane of aluminum nitride, RC(100) is measured by a ϕ-scan of the surface of the first layer, and a half width of RC(100) is from 0° to 0.8°.

The half width of RC(002) may be from 0.003° to 0.2°, and the half width of RC(100) may be from 0.003° to 0.4°.

The first layer may contain a region in which a total content of the additive element is from 0.1 ppm by mass to 200 ppm by mass.

The substrate according to an aspect of the first present invention may be used for a light emitting element.

A light emitting element according to an aspect of the first present invention contains the above-described substrate.

The light emitting element according to an aspect of the first present invention may contain the above-described substrate; an n-type semiconductor layer stacked on the first layer; a light emitting layer stacked on the n-type semiconductor layer; and a p-type semiconductor layer stacked on the light emitting layer.

### Second Present Invention

A substrate according to an aspect of a second present invention contains a first layer, a second layer, and an intermediate layer interposed between the first layer and the second layer, the first layer contains crystalline aluminum nitride, the second layer contains crystalline α-alumina, the intermediate layer contains aluminum, nitrogen, oxygen, and an additive element, the additive element is at least one selected from the group consisting of rare earth elements, alkaline earth elements, and alkali metal elements, and a maximum value of a concentration of the additive element in the intermediate layer is from 0.1 ppm by mass to 200 ppm by mass.

A content of nitrogen in the intermediate layer may decrease along a direction from the first layer toward the second layer, and a content of oxygen in the intermediate layer may increase along the direction from the first layer toward the second layer.

A thickness of the intermediate layer may be from 5 nm to 500 nm.

The maximum value of the concentration of the additive element in the intermediate layer may be from 0.5 ppm by mass to 100 ppm by mass.

The additive element may include at least any one of europium and calcium.

A light emitting element according to an aspect of the second present invention contains the above-described substrate.

### Advantageous Effects of Invention

According to the first present invention, a substrate that reduces the standard deviation of the wavelength of light emitted from a light emitting element, and a light emitting element containing the substrate are provided.

According to the second present invention, a substrate that is less likely to crack and has a smooth surface, and a light emitting element containing the substrate are provided.

### BRIEF DESCRIPTION OF DRAWINGS

FIG. 1 is a schematic cross-sectional view of a substrate according to an embodiment of the first present invention.

FIG. 2 is a schematic perspective view of a unit cell of the crystal structure of aluminum nitride.

FIG. 3 is a schematic diagram illustrating a (002) plane and a (100) plane of the unit cell shown in FIG. 2.

FIG. 4 is a schematic diagram illustrating a measurement method (ω-scan) for a rocking curve of diffracted X-rays originating from the (002) plane of aluminum nitride.

FIG. 5 is a schematic diagram illustrating a measurement method (ϕ-scan) for a rocking curve of diffracted X-rays originating from the (100) plane of aluminum nitride.

FIG. 6 shows an example of the rocking curve of diffracted X-rays originating from the (002) plane of aluminum nitride.

FIG. 7 shows an example of the rocking curve of diffracted X-rays originating from the (100) plane of aluminum nitride.

FIG. 8 is a schematic cross-sectional view of a light emitting element containing a substrate according to an embodiment of the first present invention.

FIG. 9 is a schematic perspective view of a substrate according to an embodiment of the second present invention.

FIG. 10 is a schematic cross-sectional view of the substrate shown in FIG. 9.

FIG. 11 is a schematic cross-sectional view of a light emitting element having the substrate according to an embodiment of the second present invention.

FIG. 12 shows an example of the distribution of each of nitrogen, oxygen, and the additive element in the substrate.

### DESCRIPTION OF EMBODIMENTS

### Embodiment of First Present Invention

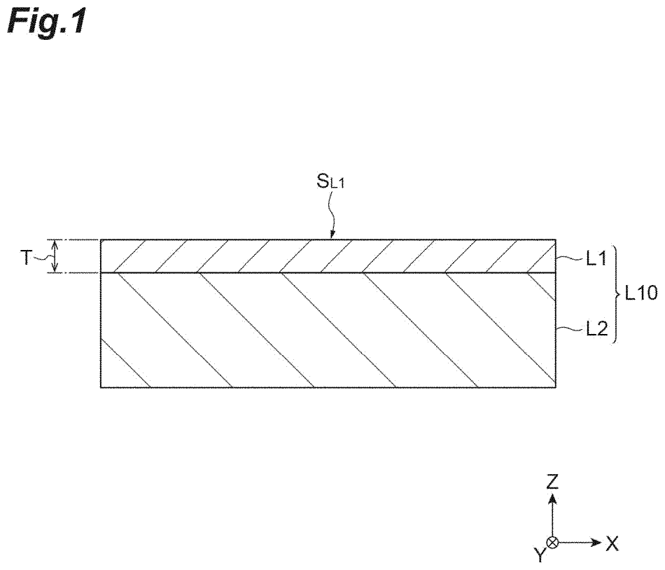

In the following description, a suitable embodiment of the first present invention will be described with reference to the drawings. The embodiment of the first present invention will be described as first embodiment. In the drawings, equivalent constituent elements will be assigned with the same reference numerals. The first present invention is not intended to be limited to the following first embodiment. X, Y, and Z shown in FIGS. 1, 4, 5, and 8 mean three coordinate axes that are orthogonal to each other. The directions indicated by the respective coordinate axes are common in FIGS. 1, 4, 5, and 8.

(Substrate)

A substrate according to the first embodiment is shown in FIG. 1. FIG. 1 is a cross-section in a ZX-plane direction of the substrate 10. In other words, FIG. 1 is a cross-section of the substrate 10 parallel to a thickness direction Z of the substrate 10 and is a cross-section of the substrate 10 perpendicular to a surface S_{L1} of a first layer L1. The thickness direction Z of the substrate 10 may be reworded as a depth direction from a surface of the substrate 10.

As shown in FIG. 1, the substrate 10 according to the first embodiment contains a first layer L1 and a second layer L2. The first layer L1 is stacked on the second layer L2. The first layer L1 may be stacked directly on the second layer L2.

The first layer L1 contains crystalline aluminum nitride (AlN) and an additive element M. The additive element M is at least one selected from the group consisting of rare earth elements, alkaline earth elements, and alkali metal elements. The additive element M may be contained in the crystalline aluminum nitride. The first layer L1 may consist of crystalline aluminum nitride containing the additive element M. The first layer L1 may contain a polycrystal of aluminum nitride containing the additive element M. The first layer L1 may consist of a polycrystal of aluminum nitride containing the additive element M. As long as a crystallinity of aluminum nitride in the first layer L1 is not impaired, the first layer L1 may contain other elements (impurities and the like) in addition to aluminum, nitrogen, and the additive element M. For example, a region in the first layer L1 facing the second layer L2 may contain a very small amount of oxygen. The details of the additive element M contained in the first layer L1 will be described below.

The second layer L2 contains crystalline α-alumina (α-Al₂O₃). α-alumina may be reworded as aluminum oxide having a corundum structure. The second layer L2 may consist of crystalline α-alumina. The second layer L2 may consist of sapphire. Sapphire may be reworded as a single crystal of α-alumina. As long as a crystallinity of α-alumina is not impaired, the second layer L2 may contain elements other than aluminum and oxygen (impurities and the like). For example, a region in the second layer L2 facing the first layer L1 may contain a very small amount of nitrogen.

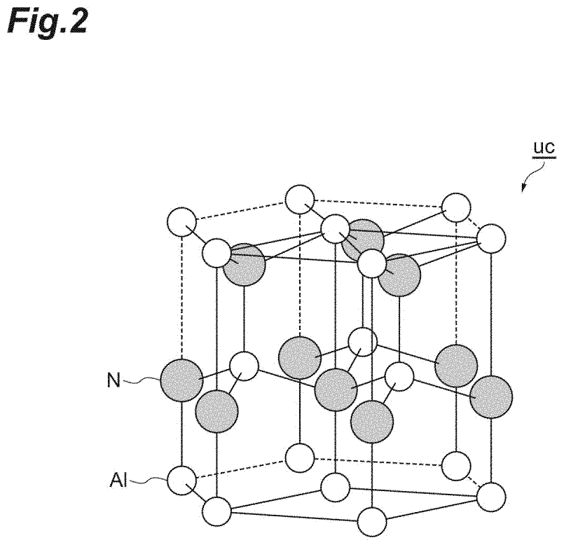

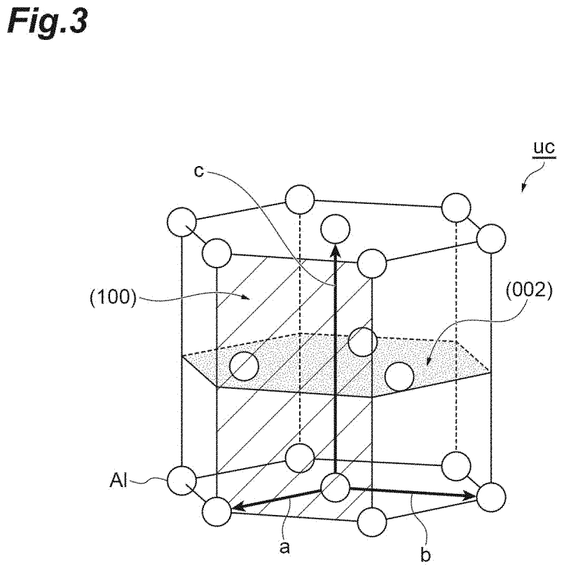

The crystal structure of aluminum nitride contained in the first layer L1 is a wurtzite type structure of a hexagonal crystal system. The crystal structure of aluminum nitride is formed of unit cells uc shown in FIG. 2. In a unit cell uc, nitrogen (N) is disposed at each of four vertices of a triangular pyramid, and aluminum (Al) is disposed inside the triangular pyramid. The unit cell uc shown in FIG. 3 is the same as the unit cell uc of FIG. 2. In FIG. 3, nitrogen is omitted in order to show the crystal planes of aluminum nitride. The reference characters a, b, and c in FIG. 3 are basic vectors constituting the unit cell uc. The orientation of a is <100>. The orientation of b is <010>. The orientation of c is <001>. <100> and <010> may be approximately parallel to the surface S_{L1} of the first layer L1. In other words, a (100) plane and a (010) plane of aluminum nitride contained in the first layer L1 may be approximately perpendicular to the surface S_{L1} of the first layer L1. <001> may be approximately perpendicular to the surface S_{L1} of the first layer L1. In other words, a (001) plane and a (002) plane of aluminum nitride contained in the first layer L1 may be approximately parallel to the surface S_{L1} of the first layer L1.

RC(002) is a rocking curve of diffracted X-rays originating from the (002) plane of aluminum nitride. The (002) plane of aluminum nitride is shown in FIG. 3. RC(002) is measured by an ω-scan of the surface S_{L1} of the first layer L1.

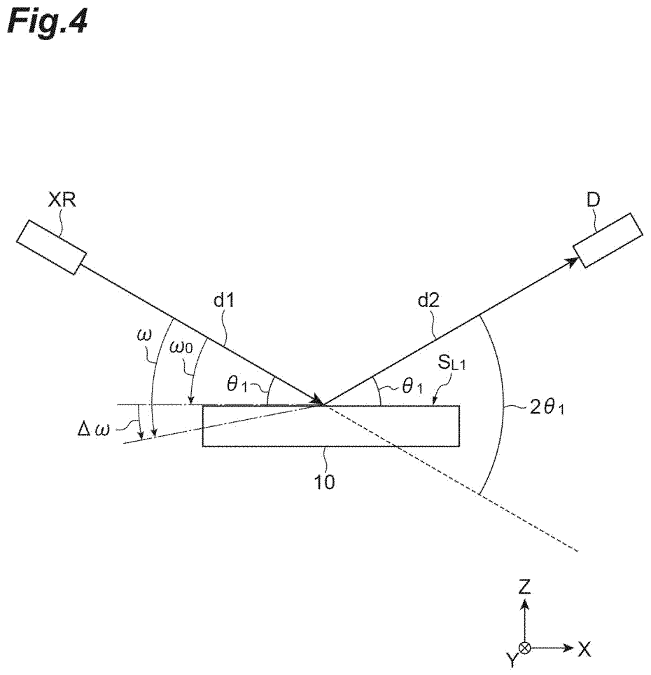

An overview of the ω-scan is shown in FIG. 4. The ω-scan is a kind of Out-of-Plane measurement. In the ω-scan, incident X-rays are irradiated from an X-ray source XR to the surface S_{L1} of the first layer L1. A direction d1 is a direction of the incident X-rays. The incident X-rays are diffracted at the (002) plane of aluminum nitride and are detected by a detector D as diffracted X-rays. When a reference point is defined as a position at which the incident X-rays are irradiated on the surface S_{L1} of the first layer L1, a direction d2 is a direction from the reference point toward the detector D. That is, the direction d2 is a direction of the detector D with respect to the position where the incident X-rays are irradiated. 2θ₁ is a diffraction angle of the diffracted X-rays originating from the (002) plane of aluminum nitride. ω is an angle between the surface S_{L1} of the first layer L1 and the direction d1 of the incident X-rays. That is, ω is a tilt angle of the surface S_{L1} of the first layer L1 with respect to the direction d1 of the incident X-rays. A unit for ω is degree (°). The ω-scan is a method of fixing an angle between the direction d1 and the direction d2 at the diffraction angle 2θ₁ and continuously measuring the intensity of the diffracted X-rays originating from the (002) plane of aluminum nitride along with the change in ω. RC(002) may be reworded as a tilt distribution of the intensity of the diffracted X-rays originating from the (002) plane of aluminum nitride.

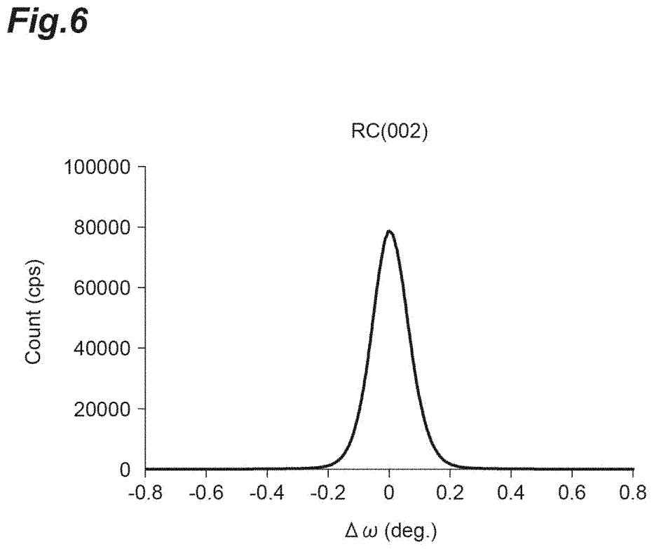

An example of RC(002) is shown in FIG. 6. The axis of abscissa of RC(002) is Δω. The axis of ordinate of RC(002) is the intensity of diffracted X-rays. A unit for the intensity of diffracted X-rays may be, for example, cps (count per second). The origin on the axis of abscissa of RC(002) corresponds to ω (that is, θ₁) at which the intensity of the diffracted X-rays originating from the (002) plane of aluminum nitride is maximum. When ω₀ is defined as ω at which the intensity of the diffracted X-rays originating from the (002) plane of aluminum nitride is maximum, RC(002) is a distribution of the intensity of the diffracted X-rays in the range of from (ω₀−Δω) to (ω₀+Δω). The incident X-rays may be characteristic X-rays of copper (Cu) (CuKα radiation), and the diffraction angle 2θ₁ of the diffracted X-rays originating from the (002) plane of aluminum nitride may be 36.00°.

RC(100) is a rocking curve of diffracted X-rays originating from the (100) plane of aluminum nitride. The (100) plane of aluminum nitride is shown in FIG. 3. RC(100) is measured by a ϕ-scan of the surface S_{L1} of the first layer L1.

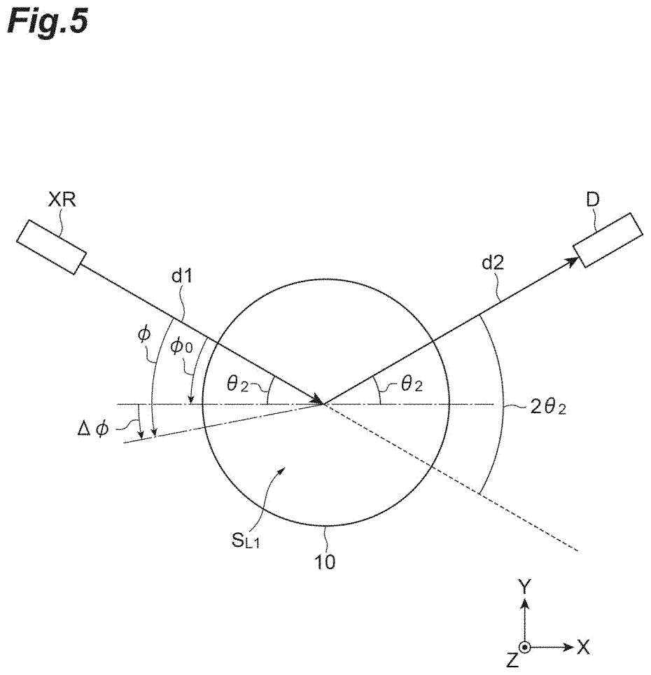

An overview of the ϕ-scan is shown in FIG. 5. The ϕ-scan is a kind of In-Plane measurement. For the convenience of explanation, the substrate 10 is a disc (wafer), and the surface S_{L1} of the first layer L1 is a circle. In the ϕ-scan, the substrate 10 rotates about the center of the surface S_{L1} of the first layer L1. That is, the center of the surface S_{L1} of the first layer L1 is the center of rotation of the substrate 10, and ϕ is an angle of rotation of the substrate 10. A unit for ϕ is degree (°). In the ϕ-scan, incident X-rays are irradiated from an X-ray source XR to the center of the surface S_{L1} of the first layer L1. A direction d1 is a direction of the incident X-rays. The incident X-rays used for the ϕ-scan are approximately parallel to the surface S_{L1} of the first layer L1. The incident X-rays are diffracted at the (100) surface of aluminum nitride and are detected by a detector D as diffracted X-rays. The diffracted X-rays measured by a ϕ-scan are approximately parallel to the surface S_{L1} of the first layer L1. When a reference point is defined as a position at which incident X-rays are irradiated to the surface S_{L1} of the first layer L1 (that is, center of the surface S_{L1}), a direction d2 is a direction from the reference point toward the detector D. That is, the direction d2 is a direction of the detector D with respect to the position where the incident X-rays are irradiated. 2θ₂ is a diffraction angle of the diffracted X-rays originating from the (100) plane of aluminum nitride. The ϕ-scan is a method of fixing an angle between the direction d1 and the direction d2 at the diffraction angle 2θ₂ and continuously measuring the intensity of the diffracted X-rays originating from the (100) plane of aluminum nitride along with the change in ϕ RC(100) may be reworded as a twist distribution of the intensity of the diffracted X-rays originating from the (100) plane of aluminum nitride.

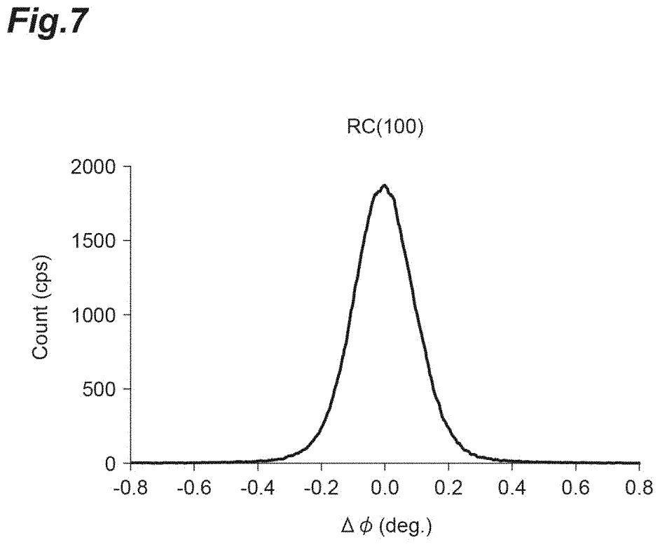

An example of RC(100) is shown in FIG. 7. The axis of abscissa of RC(100) is Δϕ. The axis of ordinate of RC(100) is the intensity of diffracted X-rays. The origin on the axis of abscissa of RC(100) corresponds to ϕ (that is, θ₂) at which the intensity of diffracted X-rays originating from the (100) plane of aluminum nitride is maximum. When ϕ₀ is defined as ϕ at which the intensity of diffracted X-rays originating from the (100) plane of aluminum nitride is maximum, RC(100) is a distribution of the intensity of diffracted X-rays in the range of from (ϕ₀−Δϕ) to (ϕ₀+Δϕ). The incident X-rays may be characteristic X-rays of copper (Cu) (CuKα radiation), and the diffraction angle 2θ₂ of the diffracted X-rays originating from the (100) plane of aluminum nitride may be 33.2θ°.

A half width of RC(002) is from 0° to 0.40. A half width of RC(100) is from 0° to 0.8°. The half width means a full width at half maximum (FWHM). As the half width of RC(002) is smaller, more (002) planes are oriented in a specific direction. The specific direction in which the (002) planes are oriented is, for example, a direction along the normal direction of the surface S_{L1} of the first layer L1. As the half width of the half width of (100) is smaller, more (100) planes are oriented in a specific direction. The specific direction in which the (100) planes are oriented is, for example, a direction along the in-plane direction of the surface S_{L1} of the first layer L1. As the half widths of both RC(002) and RC(100) are smaller, the composition of the first layer L1 is uniform, and the first layer L1 has excellent crystallinity. That is, as the half widths of both RC(002) and RC(100) are smaller, Al and N are uniformly distributed in the first layer L1, and there are fewer crystal defects of AlN in the first layer L1. When Al and N are uniformly distributed in the first layer L1, and there are fewer crystal defects of AlN in the first layer L1, the composition of each of the semiconductor layers (light emitting elements and the like) formed on the surface S_{L1} of the first layer L1 layer also becomes uniform, and the formation of crystal defects in each of the semiconductor layers is suppressed. As a result, the standard deviation a of the wavelength of light emitted from a light emitting element is reduced, and a light emitting element having a high luminous efficiency can be produced with a high yield rate. As the standard deviation a of the wavelength is smaller, the wavelength of light emitted from a light emitting element is more easily controlled to a particular value. As a result, the electric power supplied to the light emitting element is easily converted to light having a desired wavelength without waste. The present inventors have discovered that when the half width of RC(002) is from 0° to 0.4° and the half width of RC(100) is from 0° to 0.8°, the standard deviation a of the wavelength of light emitted from the light emitting element is sufficiently reduced.

The half width of RC(002) may be from 0.14° to 0.4°, and the half width of RC(100) may be from 0.22° to 0.8°. The half width of RC(002) may be from 0.150 to 0.38°, and the half width of RC(100) may be from 0.23° to 0.75°. The half width of RC(002) may be from 0.28° to 0.38°, and the half width of RC(100) may be from 0.49° to 0.75°. The half width of RC(002) may be from 0.003° to 0.2°, and the half width of RC(100) may be from 0.003° to 0.4°. When the half width of each of RC(002) and RC(100) is in the above-described range, the standard deviation a of the wavelength is likely to be reduced, and the luminous efficiency of the light emitting element is likely to increase. Since the first layer L1 is formed by nitriding of the surface of a sapphire substrate, the crystallinity of the first layer L1 is affected by the crystallinity of the sapphire substrate. Therefore, in a case where the sapphire substrate is not a perfect single crystal, the half width of each of RC(002) and RC(100) tends to be larger than zero.

The additive element M is at least one selected from the group consisting of rare earth elements, alkaline earth elements, and alkali metal elements. That is, the additive element M is at least one selected from the group consisting of scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), calcium (Ca), strontium (Sr), barium (Ba), lithium (Li), sodium (Na), potassium (K), rubidium (Rb), cesium (Cs), and radium (Ra).

In the process for producing the substrate 10, as the surface of the sapphire substrate is nitrided in the presence of the additive element M, the additive element M promotes nitriding of the surface of the sapphire substrate. As a result, a very thin first layer L1 where the half width of each of RC(002) and RC(100) is sufficiently small can be formed.

The first layer L1 may contain a region in which a total content of the additive element M is from 0.1 ppm by mass to 200 ppm by mass. In the following description, the region in which the total content of the additive element M is from 0.1 ppm by mass to 200 ppm by mass is described as additive element-including region. The additive element-including region is likely to be unevenly distributed in the vicinity of the surface S_{L1} of the first layer L1. Furthermore, the additive element-including region is likely to be unevenly distributed in the vicinity of the interface between the first layer L1 and the second layer L2. As the first layer L1 contains the additive element-including region, the surface S_{L1} of the first layer L1 is likely to become smooth. As a semiconductor layer such as a light emitting layer is laminated on a smooth surface S_{L1} of the first layer L1, crystal defects in the semiconductor layer are suppressed, and the surface of the semiconductor layer also becomes smooth. That is, the surface S_{L1} of the first layer L1 containing the additive element-including region is appropriate for the formation of the semiconductor layer. When the additive element-including region is unevenly distributed in the vicinity of the interface between the first layer L1 and the second layer L2, stress is likely to be concentrated in the additive element-including region, and warpage of the first layer L1 is likely to be suppressed. In a case where the additive element-including region contains an additive element having a larger ionic radius compared to Al, O, and N, stress is likely to be concentrated in the additive element-including region. At least a part of the additive elements contained in the additive element-including region may be at least one of Eu and Ca. As the additive element-including region contains at least one of Eu and Ca, the above-described effects attributable to the additive element-including region are easily obtained.

A thickness T of the first layer L1 is from 5 nm to 600 nm. As the thickness T of the first layer L1 is 5 nm or more, the above-described effects of the first present invention attributable to the first layer L1 are easily obtained. When the thickness T of the first layer L1 is 600 nm or less, stress hardly occur in the sapphire substrate during the process of forming the first layer L1, and warpage of the sapphire substrate is easily suppressed. As a result, a substrate 10 in which warpage is suppressed is formed. When a light emitting element is produced using this substrate 10, the standard deviation a of the wavelength of light emitted from the light emitting element is reduced. When the thickness T of the first layer L1 is more than 600 nm, the composition of the first layer L1 is likely to be non-uniform, and the crystallinity of the first layer L1 is easily deteriorated. That is, when the thickness T of the first layer L1 is more than 600 nm, it is difficult for Al and N constituting the first layer L1 to be uniformly distributed in the buffer layer, and crystal defects are easily formed in the first layer L1. As a result, the half width of RC(002) is likely to exceed 0.4°, and the half width of RC(100) is likely to exceed 0.8°. The thickness T of the first layer L1 may be from 5 nm to 200 nm, from 5 nm to 70 nm, from 5 nm to 50 nm, or from 5 nm to 10 nm. When the thickness T of the first layer L1 is in the above-described range, the standard deviation a of the wavelength is likely to be reduced, and the luminous efficiency of the light emitting element is likely to increase.

A total thickness of the substrate 10 may be, for example, from 50 μm to 3000 μm. A thickness of the second layer L2 may be a value obtained by subtracting the thickness T of the first layer L1 from the total thickness of the substrate 10. For example, the thickness of the second layer L2 may be from 49.4 μm to 2999.995 μm.

As long as the crystallinity of the first layer L1 is not impaired, an intermediate layer may be interposed between the first layer L1 and the second layer L2. That is, the first layer L1 may be stacked indirectly over the second layer L2 via an intermediate layer. The intermediate layer may contain Al, N, and O. The intermediate layer may consist of Al, N, and O. The content of N in the intermediate layer may decrease along a direction from the first layer L1 toward the second layer L2. The content of O in the intermediate layer may increase along the direction from the first layer L1 toward the second layer L2. It is desirable that the intermediate layer does not contain aluminum oxynitride (AlON), which is one of causes for light reflection.

(Method for Producing Substrate)

A method for producing the substrate 10 according to the first embodiment contains a step of adhering an additive element M to one surface of a sapphire substrate; and a nitriding treatment step of heating, in nitrogen gas, the surface of the sapphire substrate where the additive element M is adhered.

The sapphire substrate is a substrate consisting of a single crystal of α-alumina. The sapphire substrate may be a disc (wafer). A diameter of the wafer may be, for example, from 50 mm to 300 mm. As the diameter of the wafer is 50 mm or more, the standard deviation σ of the wavelength is likely to be reduced. As the diameter of the wafer is 300 mm or less, a first layer L1 consisting of a homogeneous single crystal of AlN is easily formed.

It is difficult for nitrogen to diffuse into and reach a site at a great depth from the surface of the sapphire substrate. A region where nitrogen has not diffused into and has not reached remains as the second layer containing crystalline α-alumina. On the other hand, the vicinity of the surface of the sapphire substrate where nitrogen has been introduced is sufficiently nitrided and becomes the first layer L1 containing crystalline aluminum nitride.

Before heating the sapphire substrate in nitrogen gas, the additive element M is adhered to a portion or the entirety of the surface of the sapphire substrate. For example, a solution of an organometallic compound containing the additive element M may be applied on the surface of the sapphire substrate. Furthermore, only the organic components may be decomposed and burned out by heating the solution-coated sapphire substrate in air. As the solution of the organometallic compound containing the additive element M, a solution of an organometallic compound that is used for Metal Organic Decomposition (MOD) may be used.

The sapphire substrate to which the additive element M is adhered is heated in nitrogen gas. As a result, the additive element M extracts oxygen (O²⁻) from the surface of the sapphire substrate, and oxygen defects are formed on the surface of the sapphire substrate. Nitrogen is introduced into the oxygen defects and thermally diffuses from the surface (one surface) of the sapphire substrate into the inner part of the sapphire substrate through the oxygen defects. That is, oxygen is replaced with nitrogen by a reduction nitriding reaction at the surface of the sapphire substrate. As a result, each of the first layer L1 and the second layer L2 is likely to be formed uniformly in a direction parallel to the surface of the substrate 10.

It is preferable that at least a part of the additive elements M that adheres to the surface of the sapphire substrate is at least one of europium and calcium. It is more preferable that at least a part of the additive elements M that adheres to the surface of the sapphire substrate is europium. Europium or calcium is an element having relatively low electronegativity. Therefore, when europium or calcium adheres to the surface of the sapphire substrate, europium or calcium easily extracts oxygen (O²⁻) from the surface of the sapphire substrate, and oxygen defects are easily formed at the surface of the sapphire substrate. As a result, nitrogen is likely to diffuse thermally into the sapphire substrate through the oxygen defects, and the first layer L1 and the second layer L2 are easily formed. Furthermore, europium or calcium is an element having a relatively low melting point among the additive elements M. Therefore, europium or calcium easily diffuses into the entire surface of the sapphire substrate as a semi-liquid phase even at a low temperature. As a result, each of the first layer L1 and the second layer L2 is easily formed uniformly in a direction parallel to the surface of the substrate 10.

When a temperature of the substrate to be heated in nitrogen gas reaches 1630° C. or higher, aluminum oxynitride, which is one of causes for light reflection, begins to be generated in the substrate, and aluminum oxynitride is likely to be generated especially at a temperature of 1700° C. or higher. However, when the temperature of the sapphire substrate is 1680° C. or lower, the first layer L1 and the second layer L2 can be formed while the generation of aluminum oxynitride is sufficiently suppressed, by heating the sapphire substrate to which the additive element M adhered, in nitrogen gas.

As described above, europium and calcium is likely to diffuse sufficiently into the entire surface of the sapphire substrate even at a relatively low temperature and easily extract oxygen from the surface of the sapphire substrate. Therefore, even in a case where the temperature of the sapphire substrate to be heated in nitrogen gas is a low temperature at which it is difficult for aluminum nitride to be generated, thermal diffusion of nitrogen in the sapphire substrate is likely to occur by using at least one of europium and calcium, and the first layer L1 and the second layer L2 can be easily formed. The low temperature at which it is difficult for aluminum nitride to be generated is, for example, lower than 1630° C., or 1600° C. or lower. As the additive element M is adhered to the sapphire substrate, the first layer L1 and the second layer L2 can be formed at a temperature of lower than 1630° C., while the generation of aluminum oxynitride is suppressed.

In a case where an additive element M having a higher melting point than europium and calcium is used, the sapphire substrate must be heated to a temperature higher than that in the case of using europium or calcium, in order to cause the additive element M to diffuse into the entire surface of the sapphire substrate. However, as the temperature of the sapphire substrate is higher, aluminum oxynitride, which is one of causes for light reflection, is easily generated.

The temperature of the sapphire substrate to be heated in nitrogen gas (nitriding treatment temperature) may be from 1550° C. to 1700° C., from 1600° C. to 1680° C., or 1600° C. or higher and lower than 1630° C. As described above, it is preferable that the nitriding treatment temperature is at least 1550° C. or higher in order to cause nitrogen gas to diffuse thermally into the sapphire substrate. In a case where the additive element M is not used, nitriding of sapphire proceeds at a nitriding treatment temperature of 1630° C. or higher, and at the same time, aluminum oxynitride is generated in the substrate. However, even when the nitriding treatment temperature is 1630° C. or lower, sapphire can be nitrided without generating aluminum oxynitride in the substrate, by using the additive element M. When the nitriding treatment temperature is lower than 1700° C., and more preferably 1630° C. or lower, the generation of aluminum oxynitride in the substrate can be suppressed. When the nitriding treatment temperature is lower than 1630° C. or 1600° C. or lower, aluminum nitride can be generated at the surface of the substrate by using the additive element M. When the nitriding treatment temperature is 1600° C. or higher and lower than 1630° C., smoothness of the surface of the first layer L1 containing crystalline aluminum nitride is likely to be enhanced.

The thickness and composition of the first layer L1 may be controlled by the temperature and time of the nitriding treatment, the use amount of the additive element M, and the partial pressure or supply amount of nitrogen gas. As the temperature of the sapphire substrate to be heated in nitrogen gas is higher, diffusion of nitrogen in the sapphire substrate and nitriding of sapphire are promoted. As a result, the thickness of the first layer L1 is likely to increase, and the thickness of the second layer L2 is likely to decrease. As the time for heating the sapphire substrate in nitrogen gas is longer, diffusion of nitrogen in the sapphire substrate and nitriding of sapphire are promoted. As a result, the thickness of the first layer L1 is likely to increase, and the thickness of the second layer L2 is likely to decrease. As the amount of the additive element M that adheres to the surface of the sapphire substrate and diffuses is larger, diffusion of nitrogen in the sapphire substrate and nitriding of sapphire are promoted. As a result, the thickness of the first layer L1 is likely to increase, and the thickness of the second layer L2 is likely to decrease. As the partial pressure or the supply amount of nitrogen gas is larger, diffusion of nitrogen in the sapphire substrate and nitriding of sapphire are promoted. As a result, the thickness of the first layer L1 is likely to increase, and the thickness of the second layer L2 is likely to decrease.

The nitriding treatment step is carried out at least twice. For example, after the sapphire substrate to which the additive element M is adhered is heated at the above-described nitriding treatment temperature for a short time period, the sapphire substrate may be heated at the above-described nitriding treatment temperature for a longer time period. The additive element M easily diffuses uniformly into the entire surface of the sapphire substrate through the first heating. In other words, the additive element M easily diffuses uniformly into the surface layer of the sapphire substrate through the first heating. Through the subsequent second heating for a long time period, nitrogen easily diffuses from the surface to the inner part of the sapphire substrate without unevenness. As a result, smoothness of the surface of the first layer L1 is likely to be enhanced. When the sapphire substrate is heated for a long time period without dividing the nitriding treatment into two steps, the half width of each of RC(002) and RC(100) is likely to exceed the above-described upper limit value, and smoothness of the surface of the first layer L1 is easily impaired. That is, it is difficult to produce the substrate according to the first embodiment only by a single step of nitriding treatment. The duration time of the first nitriding treatment step may be from 1 hour to 8 hours. The duration time of the second nitriding treatment step may be from 1 hour to 108 hours. The duration time of a nitriding treatment step can be reworded into the time required for heating the sapphire substrate to which the additive element M is adhered. When the duration time of the second nitriding treatment step is too long, the first layer L1 becomes thick, the composition of the first layer L1 is likely to become non-uniform, the crystallinity of the first layer L1 is easily impaired, and the half width of each of RC(002) and RC(100) is likely to increase.

The nitriding treatment of the sapphire substrate in nitrogen gas may be carried out in the presence of a carbon powder. Oxygen extracted from the sapphire substrate by the additive element M reacts with carbon in the atmosphere, and carbon monoxide is generated.

The substrate 10 according to the first embodiment is produced by the above-described production method.

(Light Emitting Element)

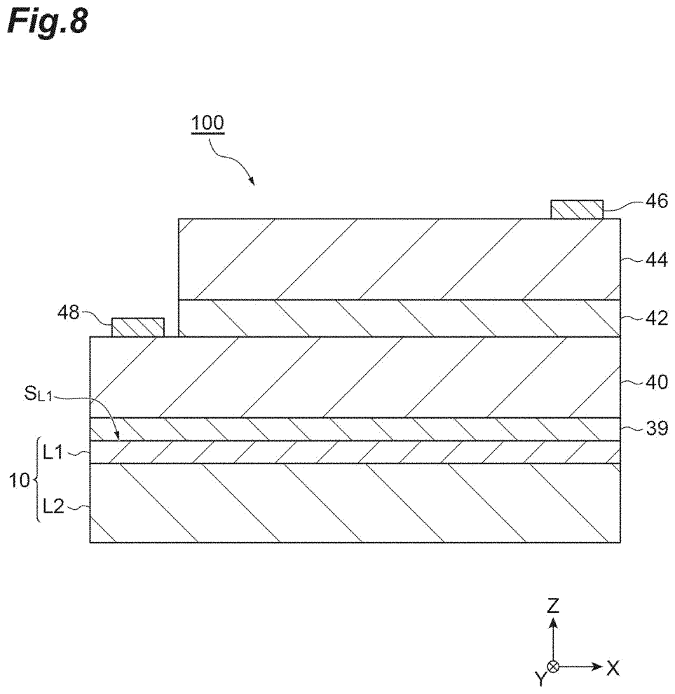

The substrate 10 according to the first embodiment may be used for a light emitting element. That is, the light emitting element according to the first embodiment contains the above-described substrate 10. As the light emitting element contains the substrate 10, the standard deviation a of the wavelength of light emitted from the light emitting element is reduced. For example, the light emitting element according to the first embodiment may be a light emitting diode. The light emitting diode may be, for example, a deep ultraviolet light emitting diode such as UVC LED or DUV LED. In the following description, a light emitting diode 100 as shown in FIG. 8 will be described as an example of a light emitting element containing the substrate 10. However, the structure of the light emitting diode according to the first embodiment is not limited to the laminated structure shown in FIG. 8.

The light emitting diode 100 according to the first embodiment contains a substrate 10; an n-type semiconductor layer 40 stacked on a first layer L1 (one surface of the substrate 10); a light emitting layer 42 stacked on the n-type semiconductor layer 40; a p-type semiconductor layer 44 stacked on the light emitting layer 42; a first electrode 48 provided on the surface of the n-type semiconductor layer 40; and a second electrode 46 provided on the surface of the p-type semiconductor layer 44. A barrier layer (electron blocking layer) may be interposed between the light emitting layer 42 and the p-type semiconductor layer 44.

The n-type semiconductor layer 40 may be stacked indirectly over the first layer L1 via a buffer layer 39. For example, the buffer layer 39 may consist of a single crystal of a nitride of a Group 13 element. For example, the buffer layer 39 may be a single crystal of a nitride of at least any one of Al and Ga. As the buffer layer 39 is disposed between the n-type semiconductor layer 40 and the first layer L1, crystal defects in each of the semiconductor layers laminated on the substrate 10 are easily suppressed. When the buffer layer 39 is sufficiently thin, the standard deviation a of the wavelength is likely to be reduced. The buffer layer 39 is not essential, and the n-type semiconductor layer 40 may be stacked directly on the first layer L1.

The n-type semiconductor layer 40 may contain, for example, n-type gallium nitride (n-GaN) or n-type aluminum gallium nitride (n-AlGaN). The n-type semiconductor layer 40 may further contain silicon (Si). The n-type semiconductor layer 40 may be composed of a plurality of layers. The light emitting layer 42 may contain, for example, gallium nitride (GaN), aluminum gallium nitride (AlGaN), or indium gallium nitride (InGaN). The light emitting layer 42 may be composed of a plurality of layers. The p-type semiconductor layer 44 may contain, for example, p-type gallium nitride (p-GaN) or p-type aluminum gallium nitride (p-AlGaN). The p-type semiconductor layer 44 may further contain magnesium (Mg). The p-type semiconductor layer 44 may be composed of a plurality of layers. For example, the p-type semiconductor layer 44 may have a p-type clad layer stacked on the light emitting layer 42, and a p-type contact layer stacked on the p-type clad layer. The first electrode 48 provided on the n-type semiconductor layer 40 may contain, for example, indium (In). The second electrode 46 provided on the p-type semiconductor layer 44 may contain, for example, at least any one of nickel (Ni) and gold (Au).

Thus, an embodiment of the first present invention has been described above; however, the first present invention is not intended to be limited to the above-described embodiment.

For example, the use application of the substrate 10 according to the first embodiment is not limited to a light emitting diode. The light emitting element according to the first embodiment may be a semiconductor laser oscillator. That is, the substrate 10 according to the first embodiment may be a substrate contained in a semiconductor laser oscillator such as an ultraviolet laser. The substrate 10 according to the first embodiment may be used for a power transistor.

### Embodiment of Second Present Invention

In the following description, a suitable embodiment of a second present invention will be described with reference to the drawings. The embodiment of the second present invention will be described as second embodiment. In the drawings, equivalent constituent elements will be assigned with the same reference numerals. The second present invention is not intended to be limited to the following second embodiment. X, Y, and Z shown in each diagram mean three coordinate axes that are orthogonal to each other. The directions indicated by the respective coordinate axes are common in all of the diagrams.

(Substrate)

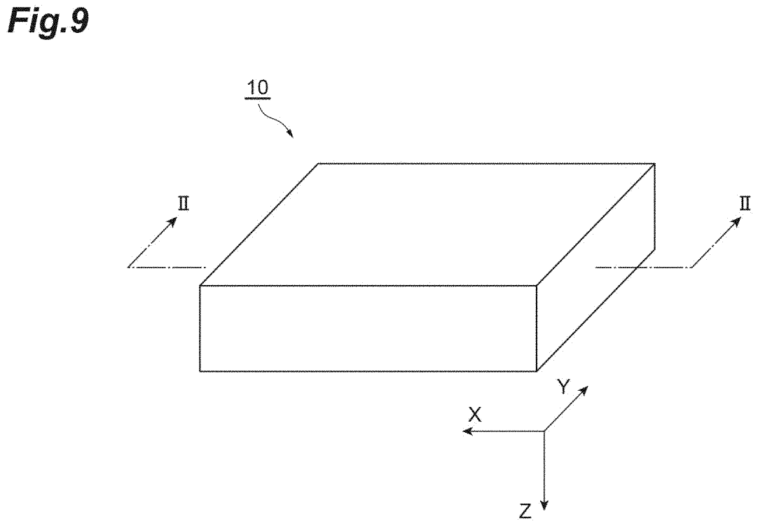

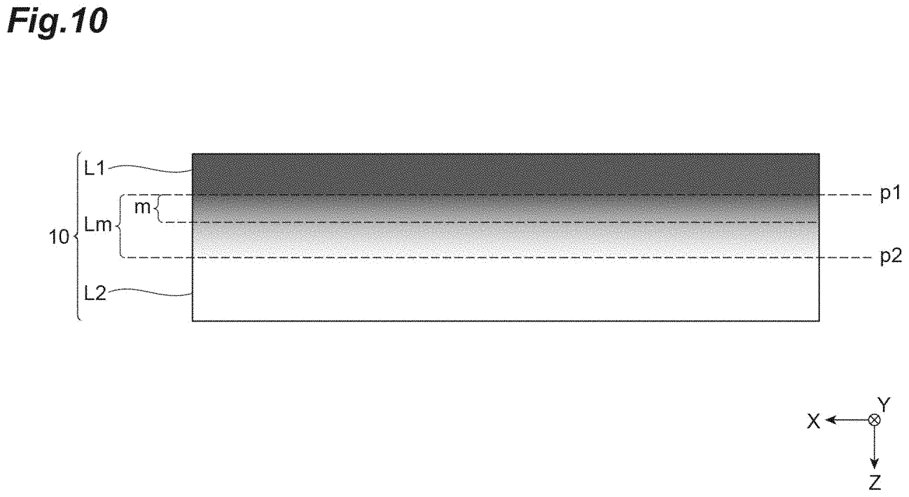

A substrate according to the second embodiment is shown in FIG. 9 and FIG. 10. FIG. 10 is a cross-section in a ZX-plane direction of the substrate 10 shown in FIG. 9. In other words, FIG. 10 is a cross-section of the substrate 10 parallel to a thickness direction Z of the substrate 10 and is a cross-section of the substrate 10 perpendicular to the surface (XY-plane direction) of the substrate 10. The thickness direction Z of the substrate 10 may be reworded as a depth direction from the surface of the substrate 10.

As shown in FIG. 10, the substrate 10 according to the second embodiment contains a first layer L1, a second layer L2, and an intermediate layer Lm interposed between the first layer L1 and the second layer L2. The first layer L1 is in direct contact with the intermediate layer Lm. The second layer L2 is also in direct contact with the intermediate layer Lm.

The first layer L1 contains crystalline aluminum nitride (AlN). The first layer L1 may consist of crystalline aluminum nitride. The first layer L1 may consist of a single crystal of aluminum nitride. However, the first layer L1 may contain elements other than aluminum and nitrogen (impurities and the like) as long as the crystallinity of aluminum nitride is not impaired. For example, a region in the first layer L1 facing the intermediate layer Lm may contain a very small amount of oxygen to the extent that does not impair the crystallinity of aluminum nitride. The region in the first layer L1 facing the intermediate layer Lm may contain a very small amount of an additive element M to the extent that does not impair the crystallinity of aluminum nitride. The details of the additive element M will be described below.

The second layer L2 contains crystalline α-alumina (α-Al₂O₃). α-alumina may be reworded as aluminum oxide having a corundum structure. The second layer L2 may consist of crystalline α-alumina. The second layer L2 may consist of sapphire. Sapphire may be reworded as a single crystal of α-alumina. As long as the crystallinity of α-alumina is not impaired, the second layer L2 may contain elements other than aluminum and oxygen (impurities and the like). For example, a region in the second layer L2 facing the intermediate layer Lm may contain a very small amount of nitrogen to the extent that does not impair the crystallinity of α-alumina. The region in the second layer L2 facing the intermediate layer Lm may contain a very small amount of the additive element M to the extent that does not impair the crystallinity of α-alumina.

The intermediate layer Lm contains aluminum (Al), nitrogen (N), oxygen (O), and an additive element (M). The additive element M is at least one selected from the group consisting of rare earth elements, alkaline earth elements, and alkali metal elements. The intermediate layer Lm may consist of Al, N, 0, and M. The intermediate layer Lm may further contain an extremely small quantity of other elements (for example, impurities) in addition to Al, N, O, and M. A maximum value of a concentration of the additive element M in the intermediate layer Lm is from 0.1 ppm by mass to 200 ppm by mass. When the intermediate layer Lm contains a plurality of kinds of additive elements M, the concentration of the additive element M in the intermediate layer Lm is a total concentration of a plurality of kinds of additive elements M contained in the intermediate layer Lm. An additive element-including region m that will be described below is a region in which the concentration of the additive element M in the intermediate layer Lm is maximum. In other words, the additive element-including region m is a region in which the concentration of the additive element M in the intermediate layer Lm is from 0.1 ppm by mass to 200 ppm by mass. The concentration of the additive element M in the intermediate layer Lm may be non-uniform, and a portion of the intermediate layer Lm may be the additive element-including region m. The concentration of the additive element M in the intermediate layer Lm may be uniform, and the entirety of the intermediate layer Lm may be the additive element-including region m. A total content of the additive elements M in a portion other than the additive element-including region m in the intermediate layer Lm may be 0 ppm by mass or more and less than 0.1 ppm by mass.

α-alumina (sapphire) and AlN differ in coefficients of thermal expansion and different lattice constants. Therefore, when the intermediate layer Lm is absent, a stress is likely to act on an interface between the first layer L1 and the second layer L2 as a result of heating the sapphire substrate and the AlN layer in the process for producing the substrate 10. As the stress is likely to act on the interface between the first layer L1 and the second layer L2, the sapphire substrate and the AlN layer are easily cracked. Cracks are easily formed in the interface where stress is concentrated. On the other hand, in a case where the intermediate layer Lm is disposed between the first layer L1 and the second layer L2, there is no interface at which the first layer L1 and the second layer L2 are in direct contact. That is, the substrate 10 does not have an interface at which stress is likely to be concentrated, unlike conventional substrates that do not contain the intermediate layer Lm. Furthermore, since at least a portion of the intermediate layer Lm is the additive element-including region m, the stress acting on the substrate 10 is likely to be dispersed in the additive element-including region m in the intermediate layer Lm. When the entirety of the intermediate layer Lm is the additive element-including region m, the stress acting on the substrate 10 is likely to be dispersed in the entirety of the intermediate layer Lm. With regard to the scale of crystal lattices, a stress caused by the difference between the crystal structures of α-alumina and AlN acts on the intermediate layer Lm. As the intermediate layer Lm contains the additive element M, the crystal lattices are easily deformed by stress, and stress is relaxed. Relaxation of the stress in the scale of the crystal lattices is caused by a tendency that an ionic radius of the cation of the additive element M is larger than an ionic radius of aluminum ion.

Due to the above-described reason, the intermediate layer Lm containing the additive element-including region m relaxes the stress locally acting on the substrate 10. As a result, cracking of the substrate 10 is suppressed.

The substrate 10 is produced by nitriding a surface of a sapphire substrate in the presence of the additive element M and carbon. The additive element M promotes nitriding of the surface of the sapphire substrate. Furthermore, as described above, the intermediate layer Lm containing the additive element-including region m relaxes the stress acting on the substrate 10 during the process for producing the substrate 10. As a result, warpage of the substrate 10 is suppressed during the process for producing the substrate 10. As the additive element M promotes nitriding during the process for producing the substrate 10 and suppresses warpage of the substrate 10, temperatures of the first layer L1 and the second layer L2 become uniform in the process of depositing the first layer L1, the surface of the sapphire substrate is uniformly nitrided, and the first layer L1 is likely to grow uniformly on the surface of the sapphire substrate. As a result, a composition of the first layer L1 becomes uniform, and a crystallinity of the first layer L1 is enhanced. In other words, Al and N constituting the first layer L1 are likely to be distributed uniformly in the first layer L1, and crystal defects in the first layer L1 are suppressed. As a result, a surface of a completed AlN layer becomes smooth. As each of the semiconductor layers is formed on the smooth surface of the AlN layer, the composition of each of the semiconductor layers becomes uniform, a crystallinity of each of the semiconductor layers is enhanced, and a surface of each of the semiconductor layers becomes smooth. As a result, cracking of the light emitting element is suppressed, and a light emitting element having a desired function can be produced at a high yield rate.

When the maximum value of the concentration of the additive element M in the intermediate layer Lm is less than 0.1 ppm by mass, a thickness of the intermediate layer Lm tends to be too small, the stress acting on the substrate 10 is not sufficiently relaxed, and the substrate 10 is easily cracked. When the maximum value of the concentration of the additive element M in the intermediate layer Lm is more than 200 ppm by mass, a thickness of the first layer L1 tends to be too large, the composition of the first layer L1 is likely to be non-uniform, crystal defects are easily formed in the first layer L1, and the surface of the first layer L1 is roughened. As a result, the composition of each of the semiconductor layers becomes non-uniform, the crystallinity of each of the semiconductor layers is impaired, and the surface of each of the semiconductor layers is also roughened. That is, when the maximum value of the concentration of the additive element M in the intermediate layer Lm is more than 200 ppm by mass, it is difficult to use the substrate 10 for the production of a light emitting element. From the viewpoint that cracking of the substrate 10 is easily suppressed and the surface of the first layer L1 is likely to become smooth, it is preferable that the maximum value of the concentration of the additive element M in the intermediate layer Lm is from 0.5 ppm by mass to 100 ppm by mass.

The thickness of the intermediate layer Lm may be from 5 nm to 500 nm. When the thickness of the intermediate layer Lm is 5 nm or more, the stress acting on the substrate 10 is likely to be relaxed sufficiently, and cracking of the substrate 10 is easily suppressed. When the thickness of the intermediate layer Lm is 500 nm or less, crystal defects in the first layer L1 are easily suppressed, and the surface of the first layer L1 is likely to become smooth. From the viewpoint that cracking of the substrate 10 is easily suppressed and the surface of the first layer L1 is likely to become smooth, it is preferable that the thickness of the intermediate layer Lm may be from 10 nm to 250 nm.

A content of nitrogen in the intermediate layer Lm may decrease along a direction (thickness direction Z of the substrate 10) from the first layer L1 toward the second layer L2. In contrast, a content of oxygen in the intermediate layer Lm may increase along the direction (thickness direction Z of the substrate 10) from the first layer L1 toward the second layer L2. As the intermediate layer Lm contains the additive element M, the distribution of each of nitrogen and oxygen in the intermediate layer Lm is likely to change gradually. Al may be distributed and dispersed in the entirety of the intermediate layer Lm. The direction from the first layer L1 toward the second layer L2 may be reworded as a depth direction. A unit of the content of each of nitrogen and oxygen may be % by mass or atom %.

The intermediate layer Lm may be a region present between a first plane p1 and a second plane p2. Both the first plane p1 and the second plane p2 are not visible interfaces (boundaries) between layers and are defined based on the chemical composition as follows. A number of nitrogen atoms present in any one plane that is located in the substrate 10 and is approximately parallel to the first layer L1 and the second layer L2 is described as [N], and a number of oxygen atoms present in the same plane is described as [O]. Based on these descriptions, the first plane p1 may be defined as a plane where [N]/([O]+[N]) is 0.9, and the second plane p2 may be defined as a plane where [N]/([O]+[N]) is 0.1. The first plane p1 may be reworded as a plane that demarcates the first layer L1 and the intermediate layer Lm, based on [N]/([O]+[N]). The second plane p2 may be reworded as a plane that demarcates the second layer L2 and the intermediate layer Lm, based on [N]/([O]+[N]). The intermediate layer Lm may be a region from a plane where [N]/([O]+[N]) begins to decrease to a plane where the decrease in [N]/([O]+[N]) stops. Between the plane where [N]/([O]+[N]) begins to decrease and the plane where the decrease in [N]/([O]+[N]) ends, the stress acting on the substrate 10 may be relaxed. The thickness of the intermediate layer Lm may be defined as a distance between the first plane p1 and the second plane p2.

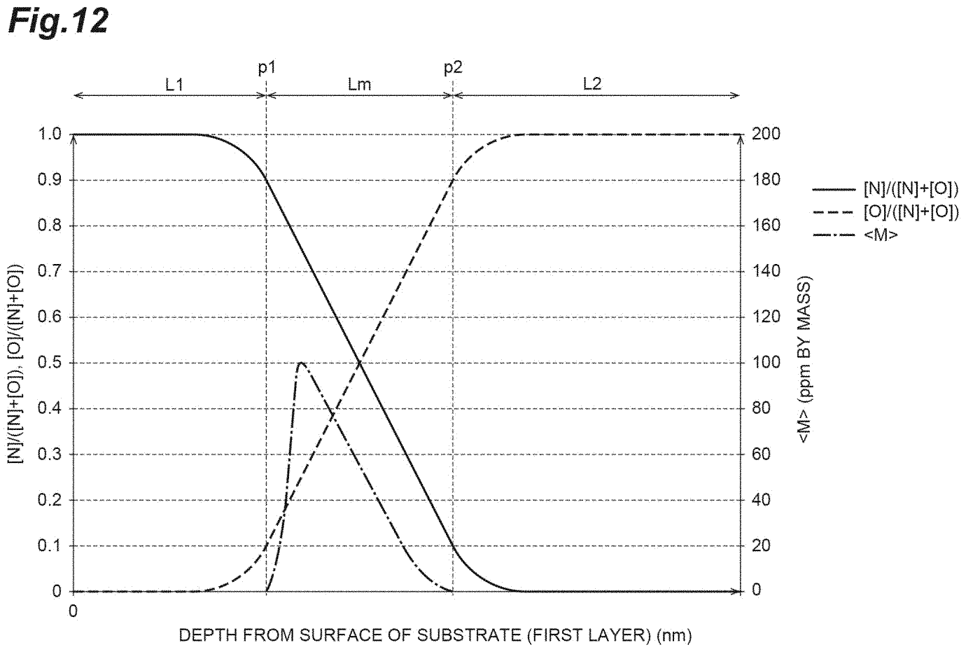

An example of a profile of each of [N]/([O]+[N]) and [O]/([O]+[N]) along the depth direction is shown in FIG. 12. An example of a profile of a concentration <M> of the additive element M along the depth direction is also shown in FIG. 12.

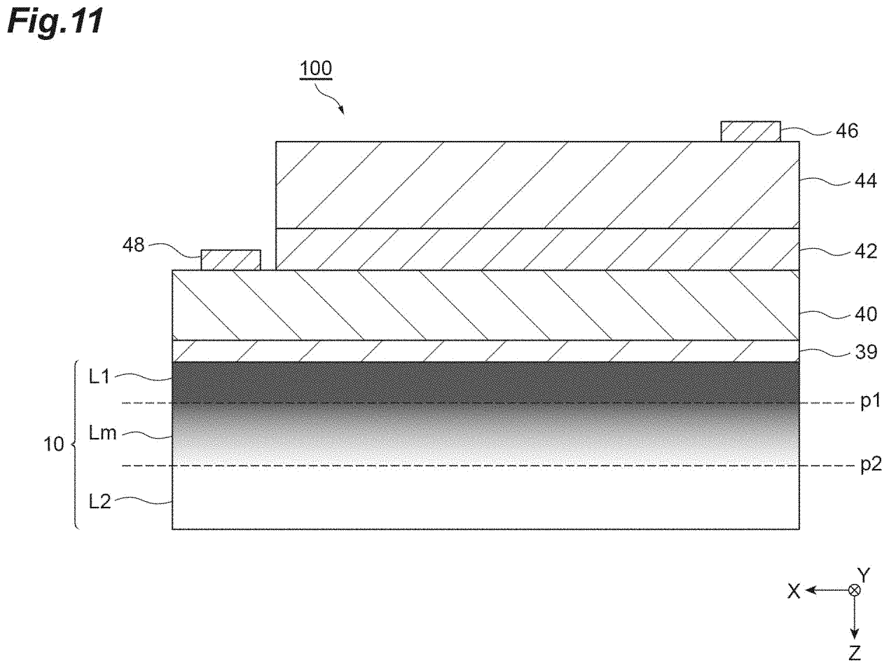

As shown in FIG. 12, a distribution of nitrogen [N]/([O]+[N]) in the intermediate layer Lm may have a gradient along the direction (thickness direction Z of the substrate 10) from the first layer L1 toward the second layer L2 and may gradually decrease along the direction from the first layer L1 toward the second layer L2. A distribution of oxygen [O]/([O]+[N]) in the intermediate layer Lm may have a gradient along the direction from the first layer L1 toward the second layer L2 and may gradually increase along the direction from the first layer L1 toward the second layer L2. In a cross-section of the intermediate layer Lm shown in FIG. 10 and FIG. 11, as a color is darker, [O]/([O]+[N]) is smaller.

As shown in FIG. 12, a composition of the intermediate layer Lm may gradually approach a composition of the second layer L2 (that is, α-alumina) along the direction from the first layer L1 toward the second layer L2. In other words, the composition of the intermediate layer Lm may gradually approach a composition of the first layer L1 (that is, aluminum nitride) along the direction from the second layer L2 toward the first layer L1. As such, the intermediate layer Lm can be regarded as a layer where α-alumina and aluminum nitride are present in mixture.

As described above, a composition of the substrate 10 may change gradually moderately) and continuously in the intermediate layer Lm. In other words, from the viewpoint that the distribution of each of nitrogen and oxygen changes continuously over the first layer L1, the intermediate layer Lm, and the second layer L2, the composition of the first layer L1 may be continuous with the composition of the intermediate layer Lm, and the composition of the intermediate layer Lm may be continuous with the composition of the second layer L2. Therefore, an interface (boundary) in crystal structure between the first layer L1 and the intermediate layer Lm does not have to exist, and an interface (boundary) in crystal structure between the intermediate layer Lm and the second layer L2 does not have to exist. For example, in a cross-section of the substrate 10 cut in parallel to the thickness direction Z of the substrate 10, interfaces corresponding to the first plane p1 and the second plane p2 do not have to exist.

As described above, the composition of the intermediate layer Lm may gradually change from AlN to Al₂O₃ in the direction from the first layer L1 toward the second layer L2. A crystal structure of the intermediate layer Lm may gradually change from a crystal structure of AlN to a crystal structure of Al₂O₃ in the direction from the first layer L1 toward the second layer L2. As the composition and the crystal structure of the intermediate layer Lm have the above-described features, the stress acting on the substrate 10 is likely to be relaxed in the intermediate layer Lm, and warpage and cracking of the substrate 10 are easily suppressed.

In a case where not the intermediate layer Lm but a third layer containing aluminum oxynitride (AlON) as a main component is interposed between the first layer L1 and the second layer L2, α-alumina (second layer L2) and aluminum oxynitride (third layer) differ in coefficients of thermal expansion and different lattice constants, and AlON and AlN (first layer L1) also differ in coefficients of thermal expansion and different lattice constants. Therefore, when an AlON layer (third layer) is disposed between the first layer L1 and the second layer L2, stress is likely to act on these interfaces, and the stress acting on the substrate 10 is not easily relaxed. As a result, the substrate 10 is easily cracked, and the surface of the first layer L1 is easily roughened. Therefore, it is desirable that the intermediate layer Lm does not contain aluminum oxynitride at all. As the intermediate layer Lm contains an additive element M, it is difficult for aluminum oxynitride to be present in the intermediate layer Lm. However, a very small amount of aluminum oxynitride may be contained in the intermediate layer Lm to the extent that the above-described effects according to the second present invention are not inhibited. The third layer may be reworded as a layer in which aluminum oxynitride as a main component is uniformly distributed, or a layer consisting of crystalline aluminum oxynitride.

As shown in FIG. 12, the concentration of the additive element M in the intermediate layer Lm may be maximum between a plane where [N]/([O]+[N]) is 1.0 and a plane where [N]/([O]+[N]) is 0.5. In other words, the additive element-including region m may be located between a plane where [N]/([O]+[N]) is 1.0 and a plane where [N]/([O]+[N]) is 0.5. In other words, a distance between the first layer L1 and the additive element-including region m may be shorter than a distance between the additive element-including region m and the second layer L2. As a result, the stress acting on the substrate 10 is easily relaxed, warpage and cracking of the substrate 10 are easily suppressed, and the surface of the first layer L1 is likely to become smooth. For similar reasons, the additive element-including region m may be a layer that is spread in a direction approximately parallel to the surface of the first layer L1.

When the composition of the substrate 10 changes gradually (moderately) and continuously in the intermediate layer Lm, a refractive index inside the substrate 10 also changes gradually (moderately) and continuously in the intermediate layer Lm. In other words, both the chemical composition and the refractive index do not easily change critically (rapidly) inside the substrate 10. Therefore, reflection of light at an interface between layers having different compositions is not likely to occur inside the substrate 10. In other words, reflection of light caused by a difference between the refractive indices of layers is not likely to occur inside the substrate 10.

In a case where not the intermediate layer Lm but a third layer containing aluminum oxynitride as a main component is interposed between the first layer L1 and the second layer L2, light is likely to be reflected inside the substrate 10 as described below.

Since aluminum oxynitride contained in the third layer is a compound that is completely different from aluminum nitride contained in the first layer L1, there is an interface (boundary in crystal structure) between the first layer L1 and the third layer, and light is likely to be reflected at this interface. In other words, since a refractive index of the third layer is completely different from a refractive index of the first layer L1, light is likely to be reflected at the interface between the first layer L1 and the third layer due to a difference in the refractive index between the first layer L and the third layer.

Furthermore, since the aluminum oxynitride contained in the third layer is a compound that is completely different from the α-alumina contained in the second layer L2, there is an interface (boundary in crystal structure) between the third layer and the second layer L2, and light is likely to be reflected at this interface. In other words, since the refractive index of the third layer is completely different from a refractive index of the second layer L2, light is likely to be reflected at the interface between the third layer and the second layer L2 due to a difference in the refractive index between the third layer and the second layer L2.

When a substrate 10 that contains not a third layer containing aluminum oxynitride as described above but an intermediate layer Lm in which the composition changes continuously is used, reflection of light attributable to aluminum oxynitride can be reduced. It is desirable that the intermediate layer Lm does not contain aluminum oxynitride at all. However, a very small amount of aluminum oxynitride may be contained in the intermediate layer Lm to the extent that the above-described effects according to the second present invention are not inhibited.

As shown in FIG. 12, [N]/([O]+[N]) in the vicinity of a region that belongs to the first layer L1 and faces the intermediate layer Lm may be more than 0.9 and 1.0 or less. In other words, [O]/([O]+[N]) in the vicinity of a region that belongs to the first layer L1 and faces the intermediate layer Lm may be 0 or more and less than 0.1. Furthermore, as shown in FIG. 12, [N]/([O]+[N]) in the vicinity of a region that belongs to the second layer L2 and faces the intermediate layer Lm may be 0 or more and less than 0.1. In other words, [O]/([O]+[N]) in the vicinity of a region that belongs to the second layer L2 and faces the intermediate layer Lm may be more than 0.9 and 1.0 or less.

A thickness of the substrate 10 may be, for example, from 50 μm to 3000 μm. A thickness of the first layer L1 may be, for example, from 50 nm to 1000 nm. A thickness of the second layer L2 may be, for example, from about 50 μm to 3000 μm.

As described above, the additive element M is at least one selected from the group consisting of rare earth elements, alkaline earth elements, and alkali metal elements. That is, the intermediate layer Lm contains at least one selected from the group consisting of scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), calcium (Ca), strontium (Sr), barium (Ba), lithium (Li), sodium (Na), potassium (K), rubidium (Rb), cesium (Cs), and radium (Ra). The intermediate layer Lm may contain a plurality of kinds of additive elements M. It is preferable that the intermediate layer Lm contains at least any one of europium and calcium as the additive element M. As a result, the stress acting on the substrate 10 is easily relaxed, warpage and cracking of the substrate 10 are easily suppressed, and the surface of the first layer L1 is likely to become smooth.

(Method for Producing Substrate)

A method for producing the substrate 10 contains a step of adhering the additive element M to one surface of a sapphire substrate; and a nitriding treatment step of heating, in nitrogen gas, the surface of the sapphire substrate to which the additive element M is adhered.

The sapphire substrate is a substrate consisting of a single crystal of α-alumina. The sapphire substrate may be a disc (wafer). A diameter of the wafer may be, for example, from 50 mm to 300 mm.

As a depth of a site from the surface of the sapphire substrate is greater, it is more difficult for nitrogen to diffuse into and reach the site. Therefore, a content of nitrogen gradually decreases along the depth direction from the surface of the sapphire substrate. As a result, the intermediate layer Lm is formed in a region where the depth from the surface of the sapphire substrate is a predetermined value or more. Then, a region where nitrogen did not diffuse into and did not reach remains as a second layer containing crystalline α-alumina. On the other hand, the vicinity of the surface of the sapphire substrate where nitrogen is introduced is sufficiently nitrided and becomes the first layer L1 containing crystalline aluminum nitride.

Before heating the sapphire substrate in nitrogen gas, the additive element M is adhered to a portion or the entirety of the surface of the sapphire substrate. For example, a solution of an organometallic compound (compound M) containing the additive element M may be applied on the surface of the sapphire substrate. Furthermore, only the organic components may be decomposed and burned out by heating the solution-coated sapphire substrate in air. As the solution of the organometallic compound containing the additive element M, for example, a solution of an organometallic compound that is used for Metal Organic Decomposition (MOD) may be used. A content of the compound M in the solution of an organometallic compound may be from 0.0005% by mass to 0.05% by mass. When the content of the compound M in the solution of the organometallic compound is in the above-described range, the maximum value of the concentration of the additive element M in the intermediate layer Lm is easily controlled to be from 0.1 ppm by mass to 200 ppm by mass, and the thickness of the intermediate layer Lm is easily controlled to be from 5 nm to 500 nm. The thickness of the intermediate layer Lm tends to increase along with an increase in the content of the compound M in the solution of the organometallic compound.

The sapphire substrate to which the additive element M is adhered is heated in nitrogen gas. As a result, the additive element M extracts oxygen (O²⁻) from the surface of the sapphire substrate, and oxygen defects are formed on the surface of the sapphire substrate. Nitrogen is introduced into the oxygen defects and thermally diffuses from the surface (one surface) of the sapphire substrate into the inner part of the sapphire substrate through the oxygen defects. That is, oxygen is replaced with nitrogen by a reduction nitriding reaction at the surface of the sapphire substrate. As a result, each of the first layer L1, the intermediate layer Lm, and the second layer L2 is likely to be formed uniformly in a direction parallel to the surface of the substrate 10.

It is preferable that at least a part of the additive elements M adhered to the surface of the sapphire substrate is at least one of europium and calcium. It is more preferable that at least a part of the additive element M adhered to the surface of the sapphire substrate is europium. Europium or calcium is an element having relatively low electronegativity. Therefore, when europium or calcium is adhered to the surface of the sapphire substrate, europium or calcium easily extracts oxygen (O²⁻) from the surface of the sapphire substrate, and oxygen defects are easily formed at the surface of the sapphire substrate. As a result, nitrogen is likely to diffuse thermally into the sapphire substrate through the oxygen defects, and the first layer L1, the intermediate layer Lm, and the second layer L2 are easily formed. Furthermore, europium or calcium is an element having a relatively low melting point among the additive elements M. Therefore, europium or calcium easily diffuses into the entire surface of the sapphire substrate as a semi-liquid phase even at a low temperature. As a result, each of the first layer L1, the intermediate layer Lm, and the second layer L2 is easily formed uniformly in a direction parallel to the surface of the substrate 10.

When a temperature of the substrate to be heated in nitrogen gas reaches 1630° C. or higher, aluminum oxynitride begins to be generated in the substrate, and aluminum oxynitride is likely to be generated especially at a temperature of 1700° C. or higher. However, when the temperature of the sapphire substrate is 1680° C. or lower, the first layer L1, the intermediate layer Lm, and the second layer L2 can be formed while the generation of aluminum oxynitride is sufficiently suppressed, by heating the sapphire substrate to which the additive element M has adhered, in nitrogen gas.

As described above, europium and calcium is likely to diffuse sufficiently into the entire surface of the sapphire substrate even at a relatively low temperature and easily extract oxygen from the surface of the sapphire substrate. Therefore, even in a case where the temperature of the sapphire substrate to be heated in nitrogen gas is a low temperature at which it is difficult for aluminum nitride to be generated, thermal diffusion of nitrogen in the sapphire substrate is likely to occur by using at least one of europium and calcium, and the first layer L1, the intermediate layer Lm, and the second layer L2 can be easily formed. The low temperature at which it is difficult for aluminum nitride to be generated is, for example, lower than 1630° C., or 1600° C. or lower. As the additive element M is adhered to the sapphire substrate, the first layer L1, the intermediate layer Lm, and the second layer L2 can be formed at a temperature of lower than 1630° C., while the generation of aluminum oxynitride is suppressed.

In a case where an additive element M having a higher melting point than europium and calcium is used, the sapphire substrate must be heated to a temperature higher than that in the case of using europium or calcium, in order to cause the additive element M to diffuse into the entire surface of the sapphire substrate. However, as the temperature of the sapphire substrate is higher, aluminum oxynitride is easily generated.

The temperature of the sapphire substrate to be heated in nitrogen gas (nitriding treatment temperature) may be from 1550° C. to 1700° C., from 1600° C. to 1680° C., or 1600° C. or higher and lower than 1630° C. As described above, it is preferable that the nitriding treatment temperature is at least 1550° C. or higher in order to cause nitrogen gas to thermally diffuse into the sapphire substrate. In a case where the additive element M is not used, nitriding of sapphire proceeds at a nitriding treatment temperature of 1630° C. or higher, and at the same time, aluminum oxynitride is generated in the substrate. On the other hand, in the case of using the additive element M, sapphire can be nitrided without generating aluminum oxynitride in the substrate at a nitriding treatment temperature of 1630° C. or lower. When the nitriding treatment temperature is lower than 1700° C., and more preferably 1630° C. or lower, the generation of aluminum oxynitride in the substrate can be suppressed. When the nitriding treatment temperature is lower than 1630° C. or 1600° C. or lower, aluminum nitride can be generated at the surface of the substrate by using the additive element M. When the nitriding treatment temperature is 1600° C. or higher and lower than 1630° C., smoothness of the surface of the first layer L1 containing crystalline aluminum nitride is likely to be enhanced.

A thickness and composition of each of the first layer L1 and the intermediate layer Lm may be controlled by the temperature and time of the nitriding treatment, an use amount of the additive element M, and a partial pressure or supply amount of nitrogen gas. As the temperature of the sapphire substrate to be heated in nitrogen gas is higher, diffusion of nitrogen in the sapphire substrate and nitriding of sapphire are promoted. As a result, the thickness of each of the first layer L1 and the intermediate layer Lm is likely to increase, and the thickness of the second layer L2 is likely to decrease. As the time for heating the sapphire substrate in nitrogen gas is longer, diffusion of nitrogen in the sapphire substrate and nitriding of sapphire are promoted. As a result, the thickness of each of the first layer L1 and the intermediate layer Lm is likely to increase, and the thickness of the second layer L2 is likely to decrease. As the amount of the additive element M that adheres to the surface of the sapphire substrate and diffuses is larger, diffusion of nitrogen in the sapphire substrate and nitriding of sapphire are promoted. As a result, the thickness of each of the first layer L1 and the intermediate layer Lm is likely to increase, and the thickness of the second layer L2 is likely to decrease. As the partial pressure or the supply amount of nitrogen gas is larger, diffusion of nitrogen in the sapphire substrate and nitriding of sapphire are promoted. As a result, the thickness of each of the first layer L1 and the intermediate layer Lm is likely to increase, and the thickness of the second layer L2 is likely to decrease.

The nitriding treatment step is carried out at least twice. For example, after the sapphire substrate to which the additive element M adheres is heated at the above-described nitriding treatment temperature for a short time period, the sapphire substrate may be heated at the above-described nitriding treatment temperature for a longer time period. The additive element M is likely to diffuse uniformly into the entire surface of the sapphire substrate through the first beating. In other words, the additive element M is likely to diffuse uniformly into a surface layer of the sapphire substrate through the first heating. Through the subsequent second heating for a long time period, nitrogen easily diffuses from the surface into the inner part of the sapphire substrate without unevenness. As a result, smoothness of the surface of the first layer L1 is likely to be enhanced. When the sapphire substrate is heated for a long time period without dividing the nitriding treatment into two steps, smoothness of the surface of the first layer L1 is easily impaired. It is difficult to produce the substrate 10 according to the second embodiment only by a single step of nitriding treatment.

The nitriding treatment of the sapphire substrate in nitrogen gas may be carried out in the presence of a carbon powder. Oxygen extracted from the sapphire substrate by the additive element M reacts with carbon in the atmosphere, and carbon monoxide is generated.

The substrate 10 according to the second embodiment is produced by the above-described production method.

(Light Emitting Element)

The light emitting element according to the second embodiment contains the above-described substrate 10. As the light emitting element contains the substrate 10, cracking of the light emitting element is suppressed. For example, the light emitting element according to the second embodiment may be a light emitting diode. The light emitting diode may be a deep ultraviolet light emitting diode such as UVC LED or DUV LED. In the following description, a light emitting diode 100 as shown in FIG. 11 will be described as an example of a light emitting element containing the substrate 10. However, the structure of the light emitting diode 100 according to the second embodiment is not limited to the laminated structure shown in FIG. 11.

As shown in FIG. 11, the light emitting diode 100 according to the second embodiment contains a substrate 10; an n-type semiconductor layer 40 stacked directly on a first layer L1 (one surface of the substrate 10); a light emitting layer 42 stacked on the n-type semiconductor layer 40; a p-type semiconductor layer 44 stacked on the light emitting layer 42; a first electrode 48 provided on a portion of the surface of the n-type semiconductor layer 40; and a second electrode 46 provided on a portion of the surface of the p-type semiconductor layer 44. A barrier layer (electron blocking layer) may be interposed between the light emitting layer 42 and the p-type semiconductor layer 44.

The n-type semiconductor layer 40 may be stacked indirectly over the first layer L1 via a buffer layer 39. For example, the buffer layer 39 may consist of a single crystal of a nitride of a Group 13 element. For example, the buffer layer 39 may be a single crystal of a nitride of at least any one of Al and Ga. As the buffer layer 39 is disposed between the n-type semiconductor layer 40 and the first layer L1, crystal defects in each of the semiconductor layers that are laminated on the substrate 10 are easily suppressed. When the buffer layer 39 is sufficiently thin, the standard deviation a of the wavelength is likely to be reduced. The buffer layer 39 is not essential, and the n-type semiconductor layer 40 may be stacked directly on the first layer L1.

The n-type semiconductor layer 40 may contain, for example, n-type gallium nitride (n-GaN) or n-type aluminum gallium nitride (n-AlGaN). The n-type semiconductor layer 40 may further contain silicon (Si). The n-type semiconductor layer 40 may be composed of a plurality of layers. The light emitting layer 42 may contain, for example, gallium nitride (GaN), aluminum gallium nitride (AlGaN), or indium gallium nitride (InGaN). The light emitting layer 42 may be composed of a plurality of layers. The p-type semiconductor layer 44 may contain, for example, p-type gallium nitride (p-GaN) or p-type aluminum gallium nitride (p-AlGaN). The p-type semiconductor layer 44 may further contain magnesium (Mg). The p-type semiconductor layer 44 may be composed of a plurality of layers. For example, the p-type semiconductor layer 44 may have a p-type clad layer stacked on the light emitting layer 42, and a p-type contact layer stacked with the p-type clad layer. A first electrode 48 provided on the n-type semiconductor layer 40 may contain, for example, indium (In). A second electrode 46 provided on the p-type semiconductor layer 44 may contain, for example, at least any one of nickel (Ni) and gold (Au).

A light emitted from the light emitting layer 42 is irradiated in all directions through the n-type semiconductor layer 40 and the substrate 10. As described above, since the substrate 10 contains an intermediate layer Lm, the light emitted from the light emitting layer is not likely to be reflected by the substrate 10. Therefore, the light emitted from the light emitting layer 42 is easily transmitted through the substrate 10 as compared to conventional light emitting diodes containing a substrate consisting of sapphire, and the light extraction efficiency is enhanced.

An embodiment of the second present invention has been described above; however, the second present invention is not intended to be limited to the above-described embodiment.

For example, an use application of the substrate 10 according to the second embodiment is not limited to a light emitting diode. The light emitting element according to the second embodiment may be a semiconductor laser oscillator. That is, the substrate 10 according to the second embodiment may be a substrate contained in a semiconductor laser oscillator such as an ultraviolet laser. The substrate 10 according to the second embodiment may be used for a power transistor. The substrate 10 according to the second embodiment may be used for a power transistor.

### EXAMPLES

### Examples of First Present Invention

In the following description, the first present invention will be described in more detail by way of Examples and Comparative Examples; however, the first present invention is not intended to be limited by these examples.

<Production of Substrate>

### Example 1

A MOD solution was applied over the entire c-plane of a sapphire substrate by spin coating. The MOD solution contained a compound of Ca (organic compound). Ca is an additive element M. The c-plane of a sapphire substrate is a (001) plane. A diameter of the sapphire substrate was 2 inches. A thickness of the sapphire substrate was 430 μm. A concentration of the compound of Ca in the MOD solution was 0.02% by mass. The spin coating was performed for 20 seconds at 2000 rpm. The sapphire substrate on which the MOD solution had been applied was dried for 10 minutes on a hot plate at 150° C. and then was heated for 2 hours at 600° C. in air. The above-described step will be described as MOD step.

The substrate after the MOD step was mounted on a square alumina plate with dimension of 100 mm×100 mm, and 5 mg of a carbon powder was disposed at each of four spots around the substrate (20 mg of carbon in total). The dimension of the alumina plate was 100 mm in length×100 mm in width. Subsequently, the entirety of the substrate was covered with an alumina Saggar, and then the substrate was placed on a sample setting stand inside a nitriding treatment furnace. The dimension of the alumina Saggar was 75 mm in length×75 mm in width×70 mm in height. As the nitriding treatment furnace, a resistance heating type electric furnace having carbon as a heater was used. Before the substrate was heated in the nitriding treatment furnace, the inside of the furnace was deaired to 0.03 Pa using a rotary pump and a diffusion pump. Next, nitrogen gas was allowed to flow into the furnace until the pressure inside the furnace reached 100 kPa (atmospheric pressure), and then the supply of nitrogen gas was stopped. Subsequently, in a first nitriding treatment, the substrate inside the furnace was heated for 1 hour at 1600° C. The rate of increase and decrease of temperature inside the furnace during the nitriding treatment was adjusted to 600° C./hour. After the nitriding treatment, the substrate was cooled to room temperature, and then the substrate was taken out of the furnace.

The substrate after the first nitriding treatment was mounted on an alumina plate. The dimension of the alumina plate was 100 mm in length×100 mm in width. 20 mg of a carbon powder was disposed at each of four spots around the substrate (80 mg of carbon in total). Subsequently, the entirety of the substrate was covered with the above-described alumina Saggar, and then the substrate was placed on a sample setting stand inside the above-described nitriding treatment furnace. The inside of the furnace was deaired to 0.03 Pa using a rotary pump and a diffusion pump. Next, nitrogen gas was allowed to flow into the furnace until the pressure inside the furnace reached 100 kPa (atmospheric pressure), and then the supply of nitrogen gas was stopped. Subsequently, in a second nitriding treatment, the substrate inside the furnace was heated for 13 hours at 1600° C. The rate of increase and decrease of temperature inside the furnace during the second nitriding treatment was adjusted to 600° C./hour. After the second nitriding treatment, the substrate was cooled to room temperature, and then the substrate was taken out of the furnace. In the following description, the duration time of the second nitriding treatment will be described as second nitriding time.

A substrate of Example 1 was produced by the above-described procedure. For the following analysis and measurement, a plurality of the same substrates were produced as the substrate of Example 1.

### Examples 2 to 6

In production of each of the substrates of Examples 2 to 6, the second nitriding time was adjusted to the value shown in the following Table 1. The MOD solution of Example 6 contained a compound of Eu instead of a compound of Ca as the compound of the additive element M. Except for these items, each of the substrates of Examples 2 to 6 was produced.

### Comparative Example 1

In production of a substrate of Comparative Example 1, the additive element M was not used as a raw material. In the production of the substrate of Comparative Example 1, a thin film consisting of aluminum nitride was formed over the entire c-plane of a sapphire substrate by an MOCVD method. The sapphire substrate used for the production of the substrate of Comparative Example 1 was the same as the sapphire substrate used for the production of the substrate of Example 1. Since the additive element M was not used as a raw material in the production of the substrate of Comparative Example 1, the substrate of Comparative Example 1 did not contain the additive element M.

### Comparative Example 2

In production of a substrate of Comparative Example 2, a MOD solution containing an additive element M was not used. That is, in the production of the substrate of Comparative Example 2, the MOD step was not carried out. The duration time of the first nitriding treatment step of Comparative Example 2 was 10 hours. In the production of the substrate of Comparative Example 2, the second nitriding treatment step was not carried out. Except for these items, the substrate of Comparative Example 2 was produced by a method similar to that of Example 1. Since the MOD step was not carried out in the production of the substrate of Comparative Example 2, the substrate of Comparative Example 2 did not contain an additive element M.

<Analysis of Substrate>

In a following X-ray diffraction (XRD) method, characteristic X-rays of Cu (CuKα radiation) were used as incident X-rays. A surface of a substrate as described below is the surface of a substrate that has been exposed to nitrogen gas without contacting an alumina plate during the nitriding treatment. That is, the surface of the substrate as described below means a nitrided surface.

An XRD pattern of the surface of the substrate of Example 1 was measured. The XRD pattern of Example 1 had peaks of a diffracted X-rays originating from a (002) plane of AlN. Furthermore, a pole figure of a (112) plane of AlN was measured by the XRD method. The pore figure had six peaks showing 6-fold rotational symmetry. On the other hand, the XRD pattern did not have any peaks of diffracted X-rays originating from a crystal phase other than AlN and sapphire. For example, the XRD pattern did not have any peaks originating from a crystal phase of aluminum oxynitride (AlON). These measurement results showed that the surface of the substrate of Example 1 contained a single crystal of AlN.

A RC(002) of Example 1 was measured by an ω-scan of the surface of the substrate of Example 1. The RC(002) of Example 1 is shown in FIG. 6. The half width of the RC(002) will be described as HW(002). The HW(002) of Example 1 is shown in the following Table 1.

A RC(100) of Example 1 was measured by a ϕ-scan of the surface of the substrate of Example 1. The RC(100) of Example 1 is shown in FIG. 7. The half width of the RC(100) will be described as HW(100). The HW(100) of Example 1 is shown in the following Table 1.

Results of the above-described analysis showed that the single crystal layer of AlN was formed on the surface of the sapphire substrate. That is, the substrate of Example 1 contained a first layer and a second layer on which the first layer was stacked, the first layer was the single crystal of AlN, and the second layer was a single crystal of α-alumina. The (002) plane of the single crystal layer of AlN was oriented along the c-axis of the sapphire substrate. In other words, the (002) plane of the single crystal of AlN constituting the first layer was approximately parallel to the surface of the first layer.

While gradually digging the surface of the substrate of Example 1 by sputtering, a composition of the substrate was analyzed along a depth direction from the surface of the first layer. The depth direction means a direction perpendicular to the surface of the first layer. For the analysis of the composition, an electron spectroscopy for chemical analysis (ESCA) and a secondary ion mass spectrometry (SIMS) were used. Results of the analysis showed that the first layer contained Ca (additive element M). The above-mentioned additive element-including region was unevenly distributed in the vicinity of the surface of the first layer, and the additive element-including region was also unevenly distributed in the vicinity of the interface between the first layer and the second layer.

A thickness T of the first layer of Example 1 was measured with an ellipsometer. The thickness T of the first layer of Example 1 is shown in the following Table 1.

Each of the substrates of Examples 2 to 6 and Comparative Examples 1 and 2 was individually analyzed by a method similar to the case of Example 1.

In all cases of the substrates of Examples 2 to 6 and Comparative Examples 1 and 2, the substrate contained a first layer and a second layer on which the first layer was stacked, the first layer was a single crystal of AlN, and the second layer was a single crystal of α-alumina. In all cases of Examples 2 to 6 and Comparative Examples 1 and 2, the (002) plane of the single crystal of AlN was oriented along the c-axis of the sapphire substrate.

All of the first layers of Examples 2 to 6 contained the additive element M. In all cases of Examples 2 to 6, the additive element-including region was unevenly distributed in the vicinity of the surface of the first layer. Furthermore, in all cases of Examples 2 to 6, the additive element-including region was also unevenly distributed in the vicinity of the interface between the first layer and the second layer.

All of the XRD patterns of Examples 2 to 6 did not have any peaks of diffracted X-rays originating from a crystal phase other than AlN and sapphire. For example, all of the XRD patterns of Examples 2 to 6 did not have any peak originating from the crystal phase of aluminum oxynitride (AlON).

The HW(002) of each of Examples 2 to 6 and Comparative Examples 1 and 2 is shown in the following Table 1. The HW(100) of each of Examples 2 to 6 and Comparative Examples 1 and 2 is shown in the following Table 1. The thickness T of the first layer of each of Examples 2 to 6 and Comparative Examples 1 and 2 is shown in the following Table 1.

The surface of the first layer of Example 1 was analyzed with a metallurgical microscope. A root mean square surface roughness (RMS) of the surface of the first layer of Example 1 was measured by an analysis using atomic force microscopy (AFM). The surface of the first layer of each of Examples 2 to 6 and Comparative Examples 1 and 2 was analyzed by a method similar to that of Example 1. In all cases of Examples 1 to 6, the entire surface of the first layer observed with a metallurgical microscope was smooth. The RMS of the surface of the first layer of each of Examples 1 to 6 was in the range of from 0.2 nm to 0.6 nm. On the other hand, the entire surface of the first layer of Comparative Example 1 was flat, and the RMS of the surface of the first layer of Comparative Example 1 was 0.2 nm. The entire surface of the surface of the first layer of Comparative Example 2 had surface unevenness. The RMS of the surface of the first layer of Comparative Example 2 was 6.0 nm.

<Production and Analysis of Light Emitting Element>

A deep ultraviolet light emitting diode (light emitting element) of Example 1 was produced by a following method of using the substrate of Example 1. all of respective layers described below were formed by MOCVD method.

An n-type buffer layer (n-type semiconductor layer) was formed on the surface (surface of the first layer) of the substrate. A thickness of the n-type buffer layer was 2 μm. The n-type buffer layer was formed from Si-doped Al_{0.55}Ga_{0.45}N.

A light emitting layer was formed by laminating a first barrier layer, a first well layer, a second barrier layer, a second well layer, a third barrier layer, a third well layer, and a fourth barrier layer in this order on the surface of the n-type buffer layer. That is, the light emitting layer had a multi-quantum well structure composed of four barrier layers and three well layers. A thickness of each of the barrier layers was 6.0 nm. Each of the barrier layers consisted of Al_{0.55}Ga_{0.45}N. A thickness of each of the well layers was 1.5 nm. Each of the well layers consisted of Al_{0.4}Ga_{0.6}N.

A p-type clad layer was laminated on a surface of the light emitting layer, and a p-type contact layer was laminated on the surface of the p-type clad layer. A thickness of the p-type clad layer was 20 nm. The p-type clad layer consisted of Mg-doped Al_{0.55}Ga_{0.45}N. A thickness of the p-type contact layer was 60 nm. The p-type contact layer consisted of Mg-doped GaN.

A laminated body produced by the above-described method was cut and divided into a plurality of chips, and thus a light emitting diode (LED chip) of Example 1 was produced.

Each of light emitting diodes of Examples 2 to 6 and Comparative Examples 1 and 2 was produced by a method similar to that of Example 1, using each of the substrates of Examples 2 to 6 and Comparative Examples 1 and 2.

A standard deviation a of wavelength of light emitted from the light emitting diode of Example 1 was calculated by a photoluminescence method. In the photoluminescence method, electrons in the light emitting diode are excited by irradiating the light emitting diode with light. As the excited electrons return to the ground state, light is emitted from the light emitting diode. The wavelength of the light emitted from the light emitting diode is measured. The standard deviation a of the wavelength of light is calculated from a distribution of the measured wavelength of light. The wavelength of light irradiated to the light emitting diode was 192 nm. An average value of the wavelength of light emitted from the light emitting layer was 280 nm. The photoluminescence method was carried out at normal temperature. The standard deviation a of the wavelength of light in Example 1 is shown in the following Table 1.

A standard deviation a of each of Examples 2 to 6 and Comparative Example 1 was calculated by a method similar to that of Example 1. The standard deviation a of each of Examples 2 to 6 and Comparative Example 1 is shown in the following Table 1. In the photoluminescence method performed using the light emitting diode of Comparative Example 2, light was not emitted from the light emitting diode.

Ni/Au electrode was formed on the surface of each of the n-type buffer layer and the p-type contact layer of the light emitting diode of Example 1. A surface of the light emitting diode except for the electrodes and the second layer was covered with a protective film. The protective film consisted of SiO₂. An electric current was passed through between the electrodes of the light emitting diode of Example 1 undergoing above processes. The presence or absence of luminescence of the light emitting diode due to the electric current was evaluated with an illuminometer.

The presence or absence of luminescence of the light emitting diode of each of Examples 2 to 6 and Comparative Examples 1 and 2 was evaluated by a method similar to that of Example 1.

the light emitting diode of each of Examples 1 to 6 and Comparative Example 1 emitted light. The light emitting diode of Comparative Example 2 did not emit light.

TABLE 1

| | | | | Standard | | |
|---|---|---|---|---|---|---|
| | | | Thick- | deviation | | |
| | | | ness | of | Half. | Half |
| | | Second | of first | wavelength | width | width |
| | Additive | nitriding | layer | of light | HW | HW |
| | element | time | T | σ | (002) | (100) |
| | M | [hour] | [nm] | [nm] | [°] | [°] |
| Example 1 | Ca | 13 | 70 | 4.1 | 0.14 | 0.22 |
| Example 2 | Ca | 2 | 10 | 3.6 | 0.28 | 0.49 |
| Example 3 | Ca | 36 | 200 | 4.4 | 0.15 | 0.25 |
| Example 4 | Ca | 1 | 5 | 3.4 | 0.38 | 0.75 |
| Example 5 | Ca | 108 | 600 | 5.2 | 0.40 | 0.80 |
| Example 6 | Eu | 13 | 50 | 3.9 | 0.15 | 0.23 |
| Comparative | None | — | 3000 | 15.0 | 0.40 | 0.80 |
| Example 1 | | | | | | |
| Comparative | None | — | 10 | — | 0.45 | 0.90 |
| Example 2 | | | | | | |

### Examples of Second Present Invention

In the following description, the second present invention will be described in more detail by way of Examples and Comparative Examples; however, the second present invention is not intended to be limited by these examples.

### Example 11

A MOD solution was applied over the entire c-plane of a sapphire substrate by spin coating. The MOD solution contained a compound of Ca (organic compound). Ca is an additive element M. The c-plane of a sapphire substrate is a (001) plane. A diameter of the sapphire substrate was 2 inches. A thickness of the sapphire substrate was 430 μm. A concentration of the compound of Ca in the MOD solution is shown in the following Table 2. The spin coating was performed for 20 seconds at 2000 rpm. The sapphire substrate on which the MOD solution had been applied was dried for 10 minutes on a hot plate at 150° C. and then was heated for 2 hours at 600° C. in air. The above-described step will be described as MOD step.

The substrate after the MOD step was mounted on a square alumina plate with dimension of 100 mm×100 mm, and 5 mg of a carbon powder was disposed at each of four spots around the substrate (20 mg of carbon in total). The dimension of the alumina plate was 100 mm in length×100 mm in width. Subsequently, the entirety of the substrate was covered with an alumina Saggar, and then the substrate was placed on a sample setting stand inside a nitriding treatment furnace. The dimension of the alumina Saggar was 75 mm in length×75 mm in width×70 mm in height. As the nitriding treatment furnace, a resistance heating type electric furnace having carbon as a heater was used. Before the substrate was heated in the nitriding treatment furnace, the inside of the furnace was deaired to 0.03 Pa using a rotary pump and a diffusion pump. Next, nitrogen gas was allowed to flow into the furnace until the pressure inside the furnace reached 100 kPa (atmospheric pressure), and then the supply of nitrogen gas was stopped. Subsequently, in a first nitriding treatment, the substrate inside the furnace was heated for 2 hours at 1600° C. A rate of increase and decrease of temperature inside the furnace during the nitriding treatment was adjusted to 600° C./hour. After the nitriding treatment, the substrate was cooled to room temperature, and then the substrate was taken out of the furnace.

The substrate after the first nitriding treatment was mounted on an alumina plate. The dimension of the alumina plate was 100 mm in length×100 mm in width. 20 mg of a carbon powder was disposed at each of four spots around the substrate (80 mg of carbon in total). Subsequently, the entirety of the substrate was covered with the above-described alumina Saggar, and then the substrate was placed on a sample setting stand inside the above-described nitriding treatment furnace. The inside of the furnace was deaired to 0.03 Pa using a rotary pump and a diffusion pump. Next, nitrogen gas was allowed to flow into the furnace until the pressure inside the furnace reached 100 kPa (atmospheric pressure), and then the supply of nitrogen gas was stopped. Subsequently, in a second nitriding treatment, the substrate inside the furnace was heated for 12 hours at 1600° C. A rate of increase and decrease of temperature inside the furnace during the second nitriding treatment was adjusted to 600° C./hour. After the second nitriding treatment, the substrate was cooled to room temperature, and then the substrate was taken out of the furnace.

The substrate of Example 11 was produced by the above-described procedure.

### Examples 12 to 17

In production of a substrate of each of Examples 12 to 17, the concentration of the compound of Ca in the MOD solution was adjusted to a value shown in a following Table 2. The substrate of each of Examples 12 to 17 was produced by a method similar to that of Example 11, except for the MOD solution.

### Example 18

In production of a substrate of Example 18, a MOD solution containing a compound of Eu instead of a compound of Ca was used. Eu is an additive element M. A concentration of the compound of Eu in the MOD solution was adjusted to a value shown in the following Table 2. The substrate of Example 18 was produced by a method similar to that of Example 11, except for the MOD solution.

### Comparative Example 11

A thin film of aluminum nitride was formed on the entire c-plane of a sapphire substrate using a direct current magnetron sputtering method. A diameter ϕ of the sapphire substrate was 2 inches. A thickness of the thin film of aluminum nitride was 1000 nm. Metallic aluminum was used as a sputtering target. As a raw material gas, a mixed gas of nitrogen gas and argon was used. A ratio of (volume of N₂:volume of Ar) was 3:1. The sputtering power was 700 W. A temperature of the sapphire substrate during film forming was 650° C., and the film-forming time was 30 minutes.

After the above-described sputtering, the substrate was mounted on a square alumina plate with dimension of 100 mm×100 mm, and 5 mg of a carbon powder was disposed at each of four spots around the substrate (20 mg of carbon in total). Subsequently, the entirety of the substrate was covered with an alumina Saggar, and then the substrate was placed on a sample setting stand inside a nitriding treatment furnace. Before the substrate was heated in the nitriding treatment furnace, the inside of the furnace was deaired to 0.03 Pa using a rotary pump and a diffusion pump. Next, nitrogen gas was allowed to flow into the furnace until the pressure inside the furnace reached 100 kPa (atmospheric pressure), and then the supply of nitrogen gas was stopped. Subsequently, in a first nitriding treatment, the substrate inside the furnace was heated for 4 hours at 1600° C. A rate of increase and decrease of temperature inside the furnace during the nitriding treatment was adjusted to 600° C./hour. After the nitriding treatment, the substrate was cooled to room temperature, and then the substrate was taken out of the furnace. In the case of Comparative Example 11, a second nitriding treatment was not carried out.

A substrate of Comparative Example 11 was produced by the above-described procedure.

### Reference Example 11

In production of Reference Example 11, a concentration of the compound of Ca in the MOD solution was adjusted to a value shown in the following Table 2. A substrate of Reference Example 11 was produced by a method similar to that of Example 11, except for the MOD solution.

<Analysis of Substrate>

A surface of a substrate as described below is a surface of a substrate that has been exposed to nitrogen gas without contacting with the alumina plate during a nitriding treatment. That is, the surface of a substrate as described below means a nitrided surface of the substrate.

[Measurement of X-Ray Diffraction Pattern]

In a following X-ray diffraction (XRD) method, characteristic X-rays of Cu (CuKα radiation) were used as incident X-rays.

An XRD pattern of a surface of the substrate of Example 11 was measured. The XRD pattern of Example 11 had peaks of a diffracted X-rays originating from a (002) plane of AlN. Furthermore, a pole figure of a (112) plane of AlN was measured by the XRD method. The pore figure had six peaks showing 6-fold rotational symmetry. On the other hand, the XRD pattern did not have any peaks of diffracted X-rays originating from a crystal phase other than AlN and sapphire. For example, the XRD pattern did not have any peaks originating from a crystal phase of aluminum oxynitride. These measurement results showed that the surface of the substrate of Example 11 contained a single crystal of AlN.

The above-described analysis results for Example 11 showed that the nitrided surface of the sapphire substrate was a single crystal layer of AlN. The single crystal layer of AlN was oriented along the c-axis of the sapphire substrate.

The substrate of each of Examples 12 to 18, Comparative Example 11, and Reference Example 11 was individually analyzed by a method similar to the case of Example 11. In all cases of Examples 12 to 18, Comparative Example 11, and Reference Example 11, the nitrided surface of the sapphire substrate was a single crystal layer of AlN, and the single crystal layer of AlN was oriented along the c-axis of the sapphire substrate. In all cases of Examples 12 to 18, Comparative Example 11, and Reference Example 11, the XRD pattern did not have any peaks of diffracted X-rays originating from a crystal phase other than AlN and sapphire.

[Analysis of Composition and Structure of Inner Part of Substrate]

The substrate of Example 11 was split, and a fracture cross-section of the substrate was observed by scanning electron microscopy (SEM) and transmission electron microscopy (TEM). An interface (clear boundary) between a single crystal layer of aluminum nitride (first layer) and a non-nitrided sapphire layer (second layer) was not found within the fracture cross-section.

The substrate of each of Examples 12 to 18 and Comparative Example 11 was observed by SEM and TEM by a method similar to that of Example 11. In all cases of Examples 12 to 18, an interface (clear boundary) between a single crystal layer of aluminum nitride (first layer) and a non-nitrided sapphire layer (second layer) was not found within the fracture cross-section. On the other hand, in the case of Comparative Example 11, there was an interface (clear boundary) between a single crystal layer of aluminum nitride (first layer) and a non-nitrided sapphire layer (second layer).

While gradually digging the surface of the substrate of Example 11 by sputtering, a composition of the substrate was analyzed along a depth direction from the surface of the substrate. The depth direction means a Z-axis direction (direction perpendicular to the surface of the substrate 10) as shown in FIG. 9 and FIG. 10. An analysis along the depth direction means an analysis of the composition of a dug-out cross-section of the substrate (cross-section of the substrate perpendicular in the depth direction). For the analysis of the composition, an electron spectroscopy for chemical analysis (ESCA) and a secondary ion mass spectrometry (SIMS) were used. A content of each of aluminum, nitrogen, and oxygen in the substrate was measured by ESCA. A content of the additive element M in the substrate was measured by SIMS.

As a result of the analysis, it was verified that the substrate of Example 11 contained a first layer consisting of a single crystal of aluminum nitride, a second layer consisting of crystalline α-alumina, and an intermediate layer interposed between the first layer and the second layer. It was verified that the intermediate layer consisted of aluminum, nitrogen, oxygen, and Ca (additive element M). In the analysis along the depth direction, the intermediate layer was detected after the first layer was detected, and the second layer was detected after the intermediate layer was detected. It was verified that [N]/([O]+[N]) in the intermediate layer Lm decreases along a direction (depth direction) from the first layer L1 toward the second layer L2.

Furthermore, it was also verified that [O]/([O]+[N]) in the intermediate layer Lm increases along the direction (depth direction) from the first layer L1 toward the second layer L2. A depth at which [N]/([O]+[N]) is 0.9 is represented by D1. A depth at which [N]/([O]+[N]) is 0.1 is represented by D2. A thickness of the intermediate layer Lm is defined as D2−D1. The thickness (D2−D1) of the intermediate layer of Example 11 is shown in the following Table 2. A maximum value of a concentration of the additive element M in the intermediate layer was measured by the above-described method. The maximum value of the concentration of the additive element M in the intermediate layer of Example 11 is shown in the following Table 2.

The substrate of each of Examples 12 to 18 and Comparative Example 11 was analyzed by a method similar to that of Example 11 using ESCA and SIMS.

As a result of the analysis, the substrate of each of Examples 12 to 18 contained, similarly to Example 11, a first layer consisting of a single crystal of aluminum nitride, a second layer consisting of crystalline α-alumina, and an intermediate layer interposed between the first layer and the second layer. The intermediate layer of each of Examples 12 to 18 consisted of aluminum, nitrogen, oxygen, and the additive element M, similarly to Example 11. In all cases of Examples 12 to 18, similarly to Example 11, in the analysis along the depth direction, the intermediate layer was detected after the first layer was detected, and the second layer was detected after the intermediate layer was detected. In all cases of Examples 12 to 18, similarly to Example 11, [N]/([O]+[N]) in the intermediate layer Lm decreased along the direction (depth direction) from the first layer L1 toward the second layer L2. Furthermore, in all cases of Examples 12 to 18, similarly to Example 11, [O]/([O]+[N]) in the intermediate layer Lm increased along the direction (depth direction) from the first layer L1 toward the second layer L2. A thickness of the intermediate layer of each of Examples 12 to 18 is shown in the following Table 2. A maximum value of a concentration of the additive element M in the intermediate layer of each of Examples 12 to 18 is shown in the following Table 2.

On the other hand, the substrate of Comparative Example 11 contained a first layer consisting of a single crystal of aluminum nitride and a second layer consisting of crystalline α-alumina, and no other layer was present between the first layer and the second layer. That is, the first layer was stacked directly on the second layer.

As will be described below, the entire surface of the substrate of Reference Example 11 was very rough. An analysis of the substrate of Reference Example 11 along the depth direction was not carried out.

[Observation of Surface of Substrate]

The substrate of each of Examples 11 to 18 was colorless and transparent. On the other hand, the entire surface of the substrate of Comparative Example 11 was white in color. The presence or absence of cracks in the substrate of each of Examples 11 to 18, Comparative Example 11, and Reference Example 11 was investigated by visually observing the surface of each of the substrates. The results are shown in the following Table 2. “A” described in Table 2 means that cracks were not formed in the entire surface of the substrate. “B” described in Table 2 means that cracks were formed in a portion of the surface of the substrate. “C” described in Table 2 means that cracks were formed in the entire surface of the substrate.

The substrate of Comparative Example 11 was cut in a direction perpendicular to the surface of the substrate, and the cross-section was visually observed. An interface (boundary line) between a single crystal layer of AlN (first layer) and a sapphire layer (second layer) traversed the cross-section. Cracks were formed in the vicinity of the interface.

The surface of the substrate of each of Examples 11 to 18, Comparative Example 11, and Reference Example 11 was observed with a metallurgical microscope. That is, the surface of the single crystal layer of AlN of each of Examples 11 to 18, Comparative Example 11, and Reference Example 11 was observed with a metallurgical microscope. A shape of the surface of each substrate observed with a metallurgical microscope is shown in the following Table 2. “A′” described in Table 2 means that the entire surface of the substrate was smooth. “B′” described in Table 2 means that a portion of the surface of the substrate had surface unevenness. That is, the B′ means that a portion of the surface of the substrate was rough, and areas other than that portion was smooth. “C′” described in Table 2 means that the entire surface of the substrate had surface unevenness. That is, the C′ means that the entire surface of the substrate was rough. The central portion of the surface of the substrate of Example 14 was smooth; however, the vicinity of the outer periphery of the surface of the substrate of Example 14 was rough.

A root mean square surface roughness (RMS) of the surface of the substrate of Example 11 was measured by analyzing the surface of the substrate of Example 11 by atomic force microscopy (AFM). The surface of the first layers of each of Examples 12 to 18, Comparative Example 11, and Reference Example 11 was analyzed by a method similar to that of Example 11.

With regard to the entire surface of the substrate of each of Examples 11 to 13 and 15 to 18 and Comparative Example 11, the RMS was in the range of from 0.2 nm to 0.5 nm. The RMS in the smooth portion in the surface of the substrate of Example 14 was in the range of from 0.2 nm to 0.5 nm. The RMS in the rough portion in the surface of the substrate of Example 14 was in the range of from 10 nm to 30 nm. With regard to the entire surface of the substrate of Reference Example 11, the RMS was in the range of from 10 nm to 30 nm. Since the entire surface of the substrate of Reference Example 11 was too rough, the substrate of Reference Example 11 was not at all suitable for the formation of a semiconductor layer.

TABLE 2

| | | | Maximum | | | |
|---|---|---|---|---|---|---|
| | | | value of | | | |
| | | Content of | concentration | | | |
| | | compound M | of M in | Thickness of | | Snake |
| | Additive | in MOD | intermediate | intermediate | Cracking | shape |
| | element | solution | layer | layer | of | of |
| | M | (mass %) | (ppm by mass) | (nm) | substrate | substrate |
| Example 11 | Ca | 0.003 | 12 | 30 | A | A′ |
| Example 12 | Ca | 0.0005 | 0.1 | 5 | B | A′ |
| Example 13 | Ca | 0.001 | 0.5 | 10 | A | A′ |
| Example 14 | Ca | 0.05 | 200 | 500 | A | B′ |
| Example 15 | Ca | 0.025 | 100 | 250 | A | A′ |
| Example 16 | Ca | 0.01 | 40 | 100 | A | A′ |
| Example 17 | Ca | 0.006 | 24 | 60 | A | A′ |
| Example 18 | Eu | 0.006 | 20 | 40 | A | A′ |
| Comparative | — | 0. | 0 | 0 | C | A′ |
| Example 11 | | | | | | |
| Reference | Ca | 0.06 | — | — | A | C′ |
| Example 11 | | | | | | |

### INDUSTRIAL APPLICABILITY

The substrate according to the first present invention is used as, for example, a substrate for a deep ultraviolet light emitting diode.

The substrate according to the second present invention is used as, for example, a substrate for a deep ultraviolet light emitting diode.

### REFERENCE SIGNS LIST

(Reference signs in FIGS. 1 to 8) 10: substrate, 39: buffer layer, 40: n-type semiconductor layer, 42: light emitting layer, 44: p-type semiconductor layer, 46: second electrode, 48: first electrode, 100: light emitting diode, L1: first layer, L2: second layer, S_{L1}: surface of first layer L1, uc: unit cell of crystal structure of aluminum nitride, d1: direction of incident X-rays, d2: direction of detector, XR: X-ray source, D: detector of diffracted X-rays.

(Reference signs in FIGS. 9 to 12) 10: substrate, 39: buffer layer, 40: n-type semiconductor layer, 42: light emitting layer, 44: p-type semiconductor layer, 46: second electrode, 48: first electrode, 100: light emitting diode, L1: first layer, L2: second layer, Lm: intermediate layer, m: additive element-including region, p1: first plane, p2: second plane.

1: A substrate comprising a first layer and a second layer on which the first layer is stacked,
wherein the first layer contains crystalline aluminum nitride and an additive element,
the second layer contains crystalline α-alumina,
the additive element is at least one selected from the group consisting of rare earth elements, alkaline earth elements, and alkali metal elements,
a thickness of the first layer is from 5 nm to 600 nm,
RC(002) is a rocking curve of diffracted X-rays originating from a (002) plane of the aluminum nitride,
the RC(002) is measured by an ω-scan of the surface of the first layer,
a half width of the RC(002) is from 0° to 0.4°,
RC(100) is a rocking curve of diffracted X-rays originating from a (100) plane of the aluminum nitride,
the RC(100) is measured by a ϕ-scan of the surface of the first layer, and
a half width of the RC(100) is from 0° to 0.8°.

2: The substrate according to claim 1,
wherein the half width of the RC(002) is from 0.003° to 0.2°, and
the half width of the RC(100) is from 0.003° to 0.4°.

3: The substrate according to claim 1, wherein the first layer contains a region in which a total content of the additive element is from 0.1 ppm by mass to 200 ppm by mass.

4: The substrate according to claim 1, wherein the substrate is used for a light emitting element.

5: A light emitting element comprising the substrate according to claim 1.

6: The light emitting element according to claim 5, wherein the light emitting element comprises:
the substrate;
an n-type semiconductor layer stacked on the first layer;
a light emitting layer stacked on the n-type semiconductor layer; and
a p-type semiconductor layer stacked on the light emitting layer.

7: A substrate comprising a first layer, a second layer, and an intermediate layer interposed between the first layer and the second layer,
wherein the first layer contains crystalline aluminum nitride,
the second layer contains crystalline α-alumina,
the intermediate layer contains aluminum, nitrogen, oxygen, and an additive element,
the additive element is at least one selected from the group consisting of rare earth elements, alkaline earth elements, and alkali metal elements, and
a maximum value of a concentration of the additive element in the intermediate layer is from 0.1 ppm by mass to 200 ppm by mass.

8: The substrate according to claim 7,
wherein a content of nitrogen in the intermediate layer decreases along a direction from the first layer toward the second layer, and
a content of oxygen in the intermediate layer increases along the direction from the first layer toward the second layer.

9: The substrate according to claim 7, wherein a thickness of the intermediate layer is from 5 nm to 500 nm.

10: The substrate according to claim 7, wherein the maximum value of the concentration of the additive element in the intermediate layer is from 0.5 ppm by mass to 100 ppm by mass.

11: The substrate according to claim 7, wherein the additive element includes at least any one of europium and calcium.

12: A light emitting element comprising the substrate according to claim 7.
